(19) United States
(12) Patent Application Publication
(10) Pub. No.: US 2026/0279426 A1
(43) Pub. Date: Sep. 17, 2026

(54) FERROELECTRIC MEMORY DEVICES AND OPERATION METHODS THEREOF

(71) Applicant: Yangtze Memory Technologies Co., Ltd., Wuhan (CN)

(72) Inventors: Junyi LIAO, Wuhan (CN); Feng XU, Wuhan (CN); Da LI, Wuhan (CN); Ya WANG, Wuhan (CN); Guoqi JI, Wuhan (CN); Ziye ZHANG, Wuhan (CN); Xiangnan ZHAO, Wuhan (CN); Hongtao LIU, Wuhan (CN); Lei JIN, Wuhan (CN)

(21) Appl. No.: 19/180,080

(22) Filed: Apr. 15, 2025

(30) Foreign Application Priority Data
Mar. 14, 2025 (CN) 202510308479.3

(51) Int. Cl. G11C 11/22

(52) U.S. Cl. CPC G11C 11/2275; G11C 11/2259; G11C 11/2273; G11C 11/2297

(57) ABSTRACT

Systems, devices, and methods for manufacturing and operating a ferroelectric memory device are provided. In one aspect, a method of operating a ferroelectric memory device includes: performing a program operation on a first ferroelectric memory cell, including: applying a program voltage to a first word line coupled to the first ferroelectric memory cell; applying a pass voltage to a second word line coupled to a second ferroelectric memory cell; applying a first voltage to a selected top select gate (TSG); and applying a second voltage greater than the first voltage to an unselected TSG.

### CROSS-REFERENCE TO RELATED APPLICATIONS

This application claims priority to Chinese Patent Application No. 202510308479.3, filed on Mar. 14, 2025, which is hereby incorporated by reference in its entirety.

### TECHNICAL FIELD

The present disclosure relates to ferroelectric memory devices and operation methods for ferroelectric memory devices.

### BACKGROUND

Semiconductor devices may be classified into non-volatile memory devices, such as flash memory devices, NAND memory device, or ferroelectric memory devices, and volatile memory devices, such as dynamic random-access memory (DRAM). The semiconductor memory devices can have different structures with different densities of memory cells and lines on a chip. A memory device normally includes a memory array of memory cells and control circuitries. The control circuitries can facilitate operations of the memory array.

### SUMMARY

The present disclosure describes methods, devices, systems and techniques for ferroelectric memory devices and operation methods thereof.

One aspect of the present disclosure features a method of operating a ferroelectric memory device, including: performing a program operation on a first ferroelectric memory cell, including: applying a program voltage to a first word line coupled to the first ferroelectric memory cell; applying a pass voltage to a second word line coupled to a second ferroelectric memory cell; applying a first voltage to a selected top select gate (TSG); and applying a second voltage greater than the first voltage to an unselected TSG.

In some implementations, the method includes applying a back gate voltage to a first back gate line coupled to the first ferroelectric memory cell and a second back gate line coupled to the second ferroelectric memory cell; and applying a source line voltage to a source line coupled to the first ferroelectric memory cell and the second ferroelectric memory cell.

In some implementations, the method includes applying a first bit line voltage to a first bit line coupled to the first ferroelectric memory cell; and applying a second bit line voltage to a second bit line coupled to a third ferroelectric memory cell, where the second bit line voltage is smaller than the first bit line voltage.

In some implementations, the method includes applying the first bit line voltage to a third bit line.

In some implementations, the first ferroelectric memory cell includes: a front gate including a part of the first word line; a dielectric layer in contact with the front gate; a first channel layer in contact with the dielectric layer; a ferroelectric layer in contact with the first channel layer; and a first back gate in contact with the ferroelectric layer and including a part of the first back gate line, where the first channel layer is between the front gate and the first back gate, and the ferroelectric layer is between the first channel layer and the first back gate.

In some implementations, the first voltage is zero.

In some implementations, the second voltage is between 0.5V and 10V.

In some implementations, the program voltage is between 5V and 10V, the pass voltage is between 4 and 8V, and the program voltage is greater than the pass voltage.

Another aspect of the present disclosure features a method of operating a ferroelectric memory device, including: performing a read operation on a first ferroelectric memory cell, including: applying a read voltage to a first word line coupled to the first ferroelectric memory cell; applying a pass voltage to a second word line coupled to a second ferroelectric memory cell; applying a back gate voltage to a first back gate line coupled to the first ferroelectric memory cell; and applying a bit line voltage to a first bit line coupled to a first channel layer of the first ferroelectric memory cell, where the first channel layer is between the first word line and the first back gate line.

In some implementations, the method includes applying a first voltage to a selected top select gate (TSG); and applying a second voltage smaller than the first voltage to an unselected TSG.

In some implementations, the first ferroelectric memory cell includes: a front gate including a part of the first word line; a dielectric layer in contact with the front gate; the first channel layer in contact with the dielectric layer; a ferroelectric layer in contact with the first channel layer; and a first back gate in contact with the ferroelectric layer and including a part of the first back gate line, where the ferroelectric layer is between the first channel layer and the first back gate.

In some implementations, the back gate voltage is zero.

In some implementations, the bit line voltage is between 0 and 5V.

In some implementations, the read voltage is between −5V and 5V.

Another aspect of the present disclosure features a method of operating a ferroelectric memory device, including: performing an erase operation on a first ferroelectric memory cell, including: applying a first voltage to a first word line coupled to the first ferroelectric memory cell; applying a bit line voltage to a first bit line coupled to the first ferroelectric memory cell; applying a source line voltage to a source line; and applying an erase voltage to a first back gate line coupled to the first ferroelectric memory cell, the erase voltage being greater than at least one of the bit line voltage or the source line voltage.

In some implementations, at least one of the bit line voltage or the source line voltage is zero.

In some implementations, the method includes performing the erase operation on the first ferroelectric memory cell and a second ferroelectric memory cell in a same erase phase by: applying the first voltage to a second word line coupled to the second ferroelectric memory cell; applying a second bit line voltage to a second bit line coupled to the second ferroelectric memory cell; applying the source line voltage to the source line; and applying the erase voltage to a second back gate line coupled to the second ferroelectric memory cell, where the first back gate line is coupled to the second back gate line.

In some implementations, the erase voltage is between 5V and 10V.

In some implementations, the first voltage is zero.

In some implementations, the first ferroelectric memory cell includes: a front gate including a part of the first word line; a dielectric layer in contact with the front gate; a first channel layer in contact with the dielectric layer; a ferroelectric layer in contact with the first channel layer; and a first back gate in contact with the ferroelectric layer and including a part of the first back gate line, where the first channel layer is between the front gate and the first back gate, and the ferroelectric layer is between the first channel layer and the first back gate.

Another aspect of the present disclosure features a semiconductor device, including: a ferroelectric memory cell, including: a first conductive layer; a dielectric layer in contact with the first conductive layer; a channel layer in contact with the dielectric layer; a ferroelectric layer in contact with the channel layer; and a second conductive layer in contact with the ferroelectric layer, where the channel layer is between the first conductive layer and the second conductive layer, and the ferroelectric layer is between the channel layer and the second conductive layer.

In some implementations, the second conductive layer includes at least one of a metallic material or polysilicon.

In some implementations, the ferroelectric layer includes at least one of Lead Zirconate Titanate (PZT), Strontium Bismuth Tantalate (SBT), Zirconium-doped Hafnium Dioxide (Zr:HfO₂), Aluminum-doped Hafnium Dioxide (Al:HfO₂), Silicon-doped Hafnium Dioxide (Si:HfO₂), Diindium Triselenide (In₂Se₃), Indium Selenide (InSe), or Copper Indium Phosphorus Sulfide (CuInP₂S₆).

In some implementations, the semiconductor device includes a source line and a bit line, where the source line is coupled to a first end of the channel layer, and the bit line is coupled to a second end of the channel layer.

In some implementations, the semiconductor device includes a first contact structure coupled to the channel layer, and a second contact structure coupled to the second conductive layer, where the first contact structure and the second contact structure extend along a same first direction and are isolated from each other.

In some implementations, the ferroelectric memory cell includes a second dielectric layer in contact with the second conductive layer, and the second conductive layer is between the second dielectric layer and the ferroelectric layer.

In some implementations, the semiconductor device includes a first semiconductor structure including: the ferroelectric memory cell, and one or more first conductive structures, at least one of the one or more first conductive structures being coupled to the ferroelectric memory cell; and a second semiconductor structure including: one or more second conductive structures, and a control circuit coupled to at least one of the one or more second conductive structures, where the at least one of the one or more first conductive structures is in contact with a corresponding one of the one or more second conductive structures, and the control circuit is coupled to the ferroelectric memory cell through the at least one of the one or more first conductive structures and the corresponding one of the one or more second conductive structures.

Another aspect of the present disclosure features a semiconductor device, including: a stack structure of first conductive layers and isolating layers alternating with each other along a first direction; and a string structure extending in the stack structure along the first direction, the string structure including a dielectric layer, a channel layer surrounded by the dielectric layer, a ferroelectric layer surrounded by the channel layer, and a second conductive layer surrounded by the ferroelectric layer, where the channel layer is between at least one of the first conductive layers and the second conductive layer along a second direction different from the first direction, and the ferroelectric layer is between the channel layer and the second conductive layer along the second direction.

In some implementations, the second conductive layer includes at least one of a metallic material or polysilicon.

In some implementations, the ferroelectric layer includes at least one of Lead Zirconate Titanate (PZT), Strontium Bismuth Tantalate (SBT), Zirconium-doped Hafnium Dioxide (Zr:HfO₂), Aluminum-doped Hafnium Dioxide (Al:HfO₂), Silicon-doped Hafnium Dioxide (Si:HfO₂), Diindium Triselenide (In₂Se₃), Indium Selenide (InSe), or Copper Indium Phosphorus Sulfide (CuInP₂S₆).

In some implementations, the string structure includes: a plug structure at a first end of the string structure and coupled to the second conductive layer of the string structure, where a size of the plug structure along the second direction is greater than a size of the second conductive layer along the second direction.

In some implementations, the semiconductor device includes a first contact structure coupled to the channel layer, and a second contact structure coupled to the second conductive layer through the plug structure, where the first contact structure and the second contact structure extend along the first direction and are isolated from each other.

In some implementations, the string structure includes an inner layer surrounded by the second conductive layer.

In some implementations, the semiconductor device includes: a first semiconductor structure including: a memory array structure including the stack structure and the string structure, and one or more first conductive structures, at least one of the one or more first conductive structures being coupled to the memory array structure; and a second semiconductor structure including: one or more second conductive structures, and a control circuit coupled to at least one of the one or more second conductive structures, where the at least one of the one or more first conductive structures is in contact with a corresponding one of the one or more second conductive structures, and the control circuit is coupled to the memory array structure through the at least one of the one or more first conductive structures and the corresponding one of the one or more second conductive structures.

Another aspect of the present disclosure features a method, including: forming a stack structure of first conductive layers and isolating layers alternating with each other along a first direction; and forming a string structure extending in the stack structure along the first direction, the string structure including a dielectric layer, a channel layer surrounded by the dielectric layer, a ferroelectric layer surrounded by the channel layer, and a second conductive layer surrounded by the ferroelectric layer, where the channel layer is between at least one of the first conductive layers and the second conductive layer along a second direction different from the first direction, and the ferroelectric layer is between the channel layer and the second conductive layer along the second direction.

In some implementations, forming the stack structure includes forming an initial stack structure of separation layers and the isolating layers alternating with each other along the first direction, The string structure includes an inner layer. Forming the string structure extending in the stack structure includes: forming a hole extending in the initial stack structure; and depositing the dielectric layer, the channel layer, the ferroelectric layer, the second conductive layer and the inner layer into the hole.

In some implementations, the method includes forming a first plug structure in a first end of the string structure, including: recessing a portion of the inner layer in the first end of the string structure to form a first opening; and depositing a first conductive material in the first opening, where the first conductive material is in contact with the second conductive layer.

In some implementations, the method includes removing the first conductive material outside the string structure by at least one polishing process.

In some implementations, the method includes forming a second plug structure in the first end of the string structure, including: recessing a portion of the dielectric layer and the channel layer in the first end of the string structure to form a second opening; and depositing a second conductive material in the second opening, where the second conductive material is in contact with the channel layer.

In some implementations, the method includes: removing a part of the second conductive material and a part of the first conductive material that is outside the string structure by at least one polishing process.

In some implementations, forming the stack structure includes: replacing the separation layers of the initial stack structure with the first conductive layers.

In some implementations, the method includes forming a first contact structure coupled to the channel layer and a second contact structure coupled to the second conductive layer at one or more same process steps.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIG. 1A illustrates a schematic view of a cross-section of an example three-dimensional (3D) memory device.

FIG. 1B illustrates a schematic view of a cross-section of another example 3D memory device.

FIG. 1C illustrates an example 3D ferroelectric memory device with a first semiconductor structure and a second semiconductor structure.

FIG. 1D illustrates a top view of the ferroelectric memory device shown in FIG. 1C.

FIG. 2A illustrates a diagram for a multi-level cell (MLC) in a ferroelectric memory device configured to store 2 bits of data with different threshold voltage levels.

FIG. 2B illustrates a schematic two-dimensional (2D) view of an example ferroelectric memory cell.

FIG. 2C illustrates a schematic 2D view of another example ferroelectric memory cell.

FIG. 2D illustrates a side view of example ferroelectric memory cells arranged in series in an example ferroelectric memory device.

FIG. 2E illustrates a side view of example ferroelectric memory cells arranged in series in another example ferroelectric memory device.

FIG. 3A illustrates a schematic circuit diagram of an example ferroelectric memory array during a program operation.

FIG. 3B illustrates a three-dimensional schematic circuit diagram of an example ferroelectric memory array during the program operation.

FIG. 4A illustrates an example signal diagram for programming the ferroelectric memory array of FIG. 3A.

FIG. 4B illustrates an example channel potential distribution in a selected memory string during the program operation of FIG. 4A.

FIG. 4C illustrates a ferroelectric memory cell in a selected memory string during the program operation of FIG. 4A.

FIG. 4D illustrates an unselected ferroelectric memory cell in an unselected memory string during the program operation of FIG. 4A.

FIG. 4E shows another unselected ferroelectric memory cell corresponding to a second bit line during the program operation of FIG. 4A.

FIG. 5 illustrates an example simulated potential distribution in an unselected ferroelectric memory cell in an unselected memory string.

FIG. 6 illustrates a schematic circuit diagram of the example ferroelectric memory array of FIG. 3A during a read operation.

FIG. 7A illustrates an example signal diagram for reading the example ferroelectric memory array of FIG. 6.

FIG. 7B illustrates a ferroelectric memory cell in a selected memory string during the read operation of FIG. 7A.

FIGS. 7C and 7D illustrate the ferroelectric memory cell of FIG. 7B with a high voltage threshold and a low voltage threshold, respectively.

FIG. 8A illustrates an example simulated potential distribution in a reference ferroelectric memory cell that does not include a back gate.

FIG. 8B illustrates an example simulated potential distribution in an example ferroelectric memory cell according to one or more implementations of the present disclosure.

FIG. 9A illustrates a schematic circuit diagram of the example ferroelectric memory array of FIG. 3A during an erase operation.

FIG. 9B illustrates an example signal diagram for erasing the example ferroelectric memory array of FIG. 9A.

FIG. 9C illustrates voltages applied to a ferroelectric memory cell during the erase operation.

FIG. 10A is a flowchart of a process of an example method of programming a ferroelectric memory device.

FIG. 10B is a flowchart of a process of an example method of reading a ferroelectric memory device.

FIG. 10C is a flowchart of a process of an example method of erasing a ferroelectric memory device.

FIGS. 11A-11D illustrate cross-sectional views of an example ferroelectric memory device at various stages of a fabrication process.

FIG. 11E illustrates a top view of the example ferroelectric memory device of FIGS. 11A-11D at a stage of the fabrication process.

FIGS. 12A-12B illustrate cross-sectional views of another example ferroelectric memory device at various stages of a fabrication process.

FIG. 13 is a flow chart of a process of an example method to form a ferroelectric memory device.

FIG. 14 illustrates a block diagram of a system having one or more semiconductor devices.

Like reference numbers and designations in the various drawings indicate like elements. It is to be understood that the various exemplary implementations shown in the figures are merely illustrative representations and are not necessarily drawn to scale.

### DETAILED DESCRIPTION

A memory device, such as a ferroelectric memory device, can apply a program voltage to perform a programming operation to program a memory cell of the ferroelectric memory device. In some aspects, ferroelectric memory cells in a same memory bock of the ferroelectric memory device can share the same word line (WL) and can be programmed simultaneously. During the programming operation, a row decoder can select a WL associated with the memory cell to send a program voltage signal to program the ferroelectric memory cell into a target state. The unselected WLs in the ferroelectric memory block can be biased to a voltage level called “Vpass” to reduce the program disturbance on all unselected cells of the memory block.

An issue with programming a ferroelectric memory cell called “program disturb” can occur when polarization states of some electric dipoles in unselected ferroelectric memory cells become inadvertently reversed during a program operation. For example, during the program operation, the Vpass voltage can be applied to the unselected word lines corresponding to unselected memory cells. At that time, the potential difference between the gate (e.g., WL) and the channel of the unselected memory cells can form an electric field. The magnitude of the electric field may not be large enough to allow a complete reversal of polarizations of a ferroelectric layer in the ferroelectric memory cells. However, due to the electric field, charges can be trapped at the interface between the ferroelectric layer and a dielectric layer in the ferroelectric memory cell. The trapped charges may induce a polarization reversal on some of the electric dipoles in the ferroelectric layer, thereby causing data corruption. A similar disturb issue can occur during a read operation. Accordingly, the programmed ferroelectric cells may be affected during a program or a read operation. This can reduce the overall reliability of ferroelectric memory device.

Implementations of the present disclosure provide semiconductor devices and methods to form and operate such semiconductor devices. In some implementations, a method of operating a ferroelectric memory device, including: performing a program operation on a first ferroelectric memory cell, including: applying a program voltage to a first word line coupled to the first ferroelectric memory cell; applying a pass voltage to a second word line coupled to a second ferroelectric memory cell; applying a first voltage to a selected top select gate (TSG); and applying a second voltage greater than the first voltage to an unselected TSG. In some implementations, a semiconductor device includes a ferroelectric memory cell, including: a first conductive layer; a dielectric layer in contact with the first conductive layer; a channel layer in contact with the dielectric layer; a ferroelectric layer in contact with the channel layer; and a second conductive layer in contact with the ferroelectric layer, where the channel layer is between the first conductive layer and the second conductive layer, and the ferroelectric layer is between the channel layer and the second conductive layer.

Implementations of the present disclosure can provide one or more of the following technical advantages and/or benefits. For example, a ferroelectric memory cell according to one or more implementations of the present disclosure includes at least a back gate, a ferroelectric layer, and a channel layer. The ferroelectric layer can be between the channel layer and the back gate, and the channel layer can be between a front gate (e.g., a corresponding WL) and the back gate. During a program operation, in an unselected memory string, a corresponding unselected TSG can be turned on to bias the channel layer in the ferroelectric memory cell to 0V. The back gate of the ferroelectric memory cell can also be biased to 0V. Therefore, the ferroelectric layer that is between the channel layer and the back gate can experience a low electric field or zero electric field. This low electric field can reduce the risk of reversing the polarization state of the ferroelectric layer, thereby significantly reducing or eliminating program disturb.

Additionally, during a read operation, the channel layer of a ferroelectric memory cell can be biased to a bit line voltage (e.g., 0.5V) by switching on the corresponding TSG. The channel layer can shield the ferroelectric layer from the high electric fields generated by the read voltage Vread or the pass voltage Vpass applied to the word lines during the read operation. Therefore, the ferroelectric layer may only experience a low electric field or a near-zero electric field from the voltage difference between the channel layer and the back gate, thereby significantly reducing or eliminating read disturb.

Further, the techniques described in the present disclosure can enable a block erase by coupling multiple back gates together. During an erase operation, a positive voltage can be applied to the back gates and a low voltage (e.g., Vss) can be applied to at least one of bit lines or source lines. An electric field can be generated between the back gates and channel layers of the ferroelectric memory cells to erase the data by altering the polarization states of the ferroelectric layer.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

Ferroelectric Random Access Memory (FeRAM) is a high-performance and low-power non-volatile memory that can combine the benefits of conventional non-volatile memories (e.g., Flash and EEPROM) and high-speed RAM (e.g., SRAM and DRAM). FeRAM can outperform existing memories like EEPROM and Flash with less power consumption, faster response, and greater endurance to multiple read-and-write operations. There are two types of FeRAMs: capacitor type, and field-effect transistor (FET) type. A capacitor-type FeRAM cell includes at least one ferroelectric capacitor and at least one MOSFET used for cell selection, also referred to as an nTnC FeRAM memory cell. A FET-type FeRAM cell is capacitor-free and only includes a single ferroelectric-gate FET (FeFET). FET-type FeRAM can be integrated into high-density, because FeFET can be scaled down using the proportionality rule. By replacing the charge trapping storage layer in a 3D NAND flash memory with a ferroelectric material (e.g., Si:HfO₂), a 3D ferroelectric NAND flash memory can be formed.

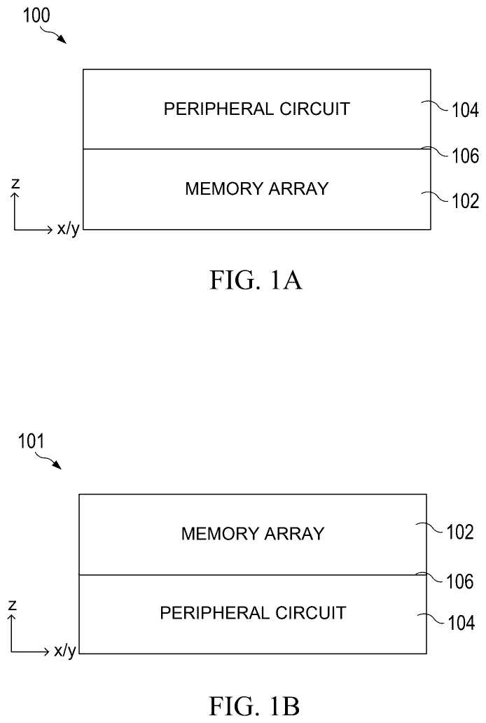

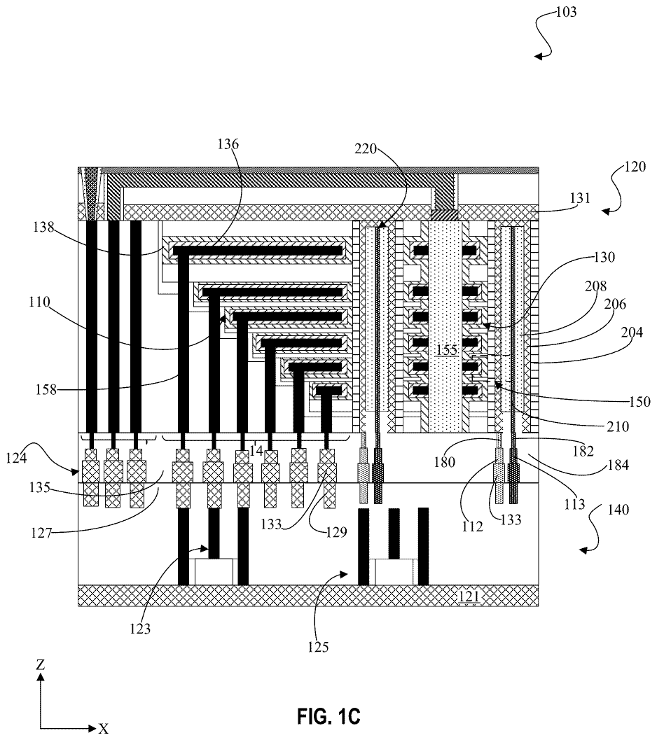

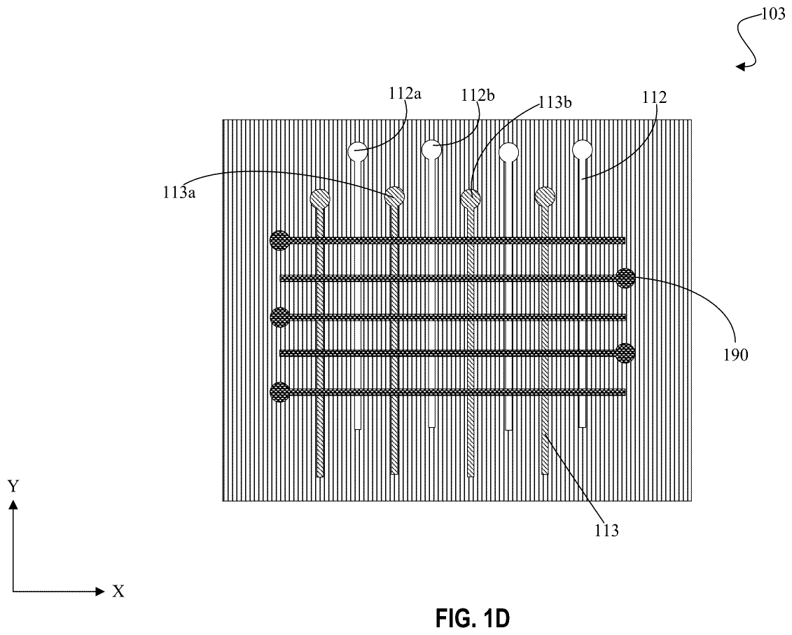

FIG. 1A illustrates a schematic view of a cross-section of an example 3D memory device 100, according to one or more implementations of the present disclosure. 3D memory device 100 represents an example of a bonded chip. The components of 3D memory device 100 (e.g., memory array and peripheral circuits) can be formed separately on different substrates and then jointed to form a bonded chip. 3D memory device 100 can include a first semiconductor structure 102 including an array of memory cells (e.g., memory array). In some implementations, the memory array includes an array of ferroelectric memory cells. For ease of description, a ferroelectric memory array may be used as an example for describing the memory array in the present disclosure.

The first semiconductor structure 102 can be a ferroelectric memory device in which memory cells are provided in the form of an array of 3D ferroelectric memory strings and/or an array of two-dimensional (2D) ferroelectric memory cells. Ferroelectric memory cells can be organized into pages or fingers, which are then organized into blocks in which each ferroelectric memory cell is electrically connected to a separate line called a bit line (BL). All cells with the same vertical level in the ferroelectric memory block can be electrically coupled to a word line (WL). In some implementations, a plane contains a certain number of blocks that are electrically connected through the same bit line. The first semiconductor structure 102 can include one or more planes, and the peripheral circuits that are needed to perform all the read/program (write)/erase operations can be included in a second semiconductor structure 104.

In some implementations, the array of ferroelectric memory cells is an array of ferroelectric memory cells, each of which includes a ferroelectric field-effective transistor (FEFET). The array of ferroelectric memory cells includes a plurality of ferroelectric memory strings, each of which includes a plurality of memory cells (e.g., 32 to 128 memory cells) connected in series and two select transistors (e.g., a top select gate transistor, a bottom select gate transistor), according to some implementations. Each ferroelectric memory string is arranged in the same plane on the substrate, according to some implementations. In some implementations, the array of ferroelectric memory cells is an array of three-dimensional (3D) ferroelectric memory strings, each of which extends vertically above the substrate (in 3D) through a stack structure, e.g., a memory stack. Depending on the 3D ferroelectric technology (e.g., the number of layers/tiers in the memory stack), a 3D ferroelectric memory string typically includes 32 to 256 ferroelectric memory cells.

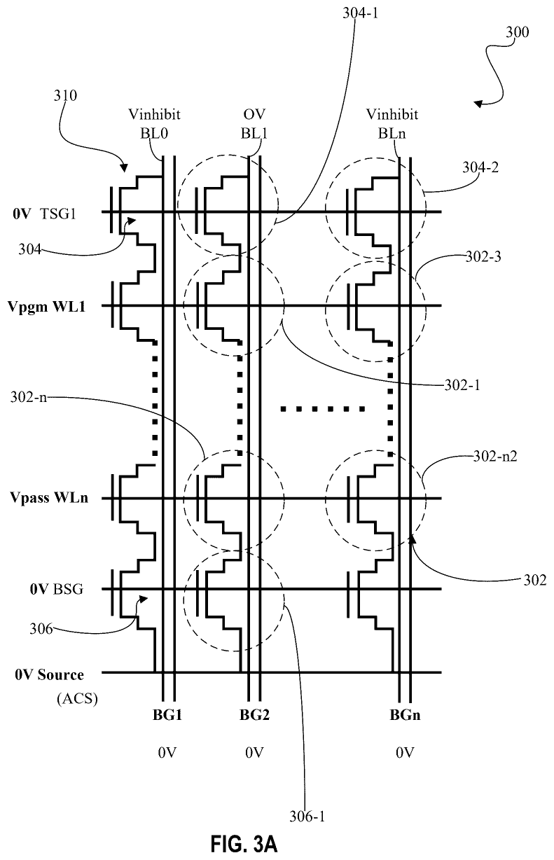

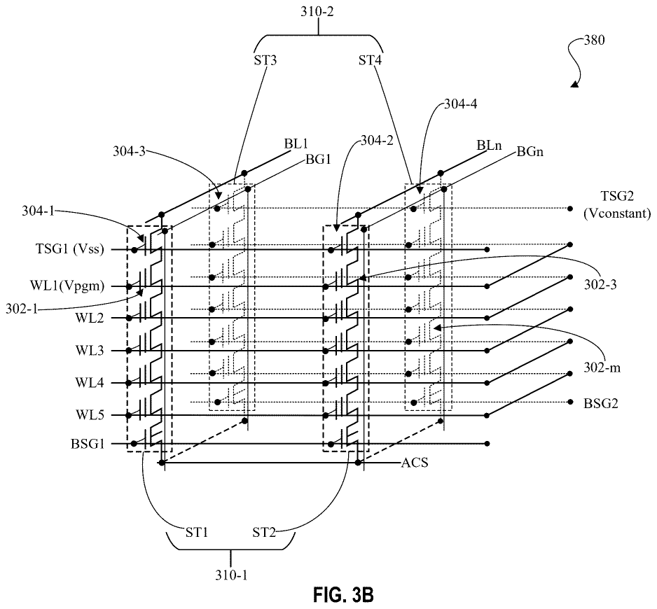

As shown in FIGS. 1A, 3D memory device 100 can also include the second semiconductor structure 104 including the peripheral circuits of the memory array of the first semiconductor structure 102. The peripheral circuits (a.k.a. control and sensing circuits) can include any suitable digital, analog, and/or mixed-signal circuits used for facilitating the operations of the memory array. For example, the peripheral circuit can include one or more of a page buffer, a decoder (e.g., a row decoder and a column decoder), a sense amplifier, a driver (e.g., a word line driver), an I/O circuit, a charge pump, a voltage source or generator, a current or voltage reference, any portions (e.g., a sub-circuit) of the functional circuits mentioned above, or any active or passive components of the circuit (e.g., transistors, diodes, resistors, or capacitors). The peripheral circuits in second semiconductor structure 104 use CMOS technology, e.g., which can be implemented with logic processes (e.g., technology nodes of 90 nm, 65 nm, 60 nm, 45 nm, 32 nm, 28 nm, etc.). As described above and below in detail, consistent with the scope of the present disclosure, the technology nodes used for fabricating the peripheral circuits in second semiconductor structure 104 can be above 22 nm in order to reduce leakage current, maintain certain voltage levels (e.g., 1.2 V and above), and reduce the cost.

As shown in FIGS. 1A, 3D memory device 100 further includes a bonding interface 106 vertically (e.g., along Z direction) between first semiconductor structure 102 and second semiconductor structure 104. In some implementations, the first and the second semiconductor structures 102 and 104 can be fabricated separately (and in parallel in some implementations) such that the thermal budget of fabricating one of first and second semiconductor structures 102 and 104 does not limit the processes of fabricating another one of first and second semiconductor structures 102 and 104. Moreover, a large number of interconnects can be formed through bonding interface 106 to make direct, short-distance (e.g., micron-level) electrical connections between first semiconductor structure 102 and second semiconductor structure 104, as opposed to the long-distance (e.g., millimeter or centimeter-level) chip-to-chip data bus on the circuit board, such as printed circuit board (PCB), thereby eliminating chip interface delay and achieving high-speed I/O throughput with reduced power consumption. Data transfer between the memory array in first semiconductor structure 102 and the peripheral circuits in second semiconductor structure 104 can be performed through the interconnects across the bonding interface 106. By vertically (e.g., along Z direction) integrating first and second semiconductor structures 102 and 104, the chip size can be reduced, and the memory cell density can be increased.

It is understood that the relative positions of stacked first and second semiconductor structures 102 and 104 are not limited. FIG. 1B illustrates a schematic view of a cross-section of an example 3D memory device 101, according to one or more implementations of the present disclosure. Different from 3D memory device 100 of FIG. 1A in which second semiconductor structure 104 including the peripheral circuits is above first semiconductor structure 102 including the memory array, in 3D memory device 101 of FIG. 1B, first semiconductor structure 102 including the memory array is above second semiconductor structure 104 including the peripheral circuits. Nevertheless, bonding interface 106 is formed vertically between first and second semiconductor structures 102 and 104 in 3D memory device 101, and first and second semiconductor structures 102 and 104 are jointed vertically through bonding (e.g., hybrid bonding) according to some implementations. Hybrid bonding, also known as “metal/dielectric hybrid bonding,” is a direct bonding technology (e.g., forming bonding between surfaces without using intermediate layers, such as solder or adhesives) and can obtain metal-metal (e.g., Cu-to-Cu) bonding and dielectric-dielectric (e.g., SiO₂-to-SiO₂) bonding simultaneously. Data transfer between the memory array in first semiconductor structure 102 and the peripheral circuits in second semiconductor structure 104 can be performed through the interconnects across bonding interface 106. In some implementations, the bonding interface 106 can include a first bonding layer in the first semiconductor structure 102 and a second bonding layer in the second semiconductor structure 104. The first bonding layer can include first conductive structures isolated by a first isolating material (e.g., SiO₂ or other dielectric material). The second bonding layer can include second conductive structures isolated by a second isolating material (e.g., SiO₂ or other dielectric material). The first isolating material and the second isolating material can be same or different, e.g., according to actual fabrication needs. Each of the second conductive structures can correspond to a first conductive structure of the first conductive structures. As such, when the first semiconductor structure 102 and the second semiconductor structure 104 are stacked together, the second conductive structures can be in contact with the corresponding first conductive structures to form conductive bonding (e.g., metal-to-metal bonding) through the bonding interface 106.

FIG. 1C illustrates an example 3D ferroelectric memory device 103 with a first semiconductor structure 120 and a second semiconductor structure 140. The 3D ferroelectric memory device 103 can be the memory device 100 of FIG. 1A, and/or the memory device 101 of FIG. 1B. The first semiconductor structure 120 can be the first semiconductor structure 102 of FIGS. 1A and 1B. The second semiconductor structure 140 can be the second semiconductor structure 104 of FIGS. 1A and 1B. As used herein, whether one component (e.g., a layer or a device) is “on,” “above,” “over” or “below” another component (e.g., a layer or a device) of a device (e.g., 3D memory device 103) is determined relative to the structure or layer in the z-direction (e.g., the vertical direction) when the structure or layer is positioned in the lowest tier of the device in the z-direction. The same notion for describing spatial relationships is applied throughout the present disclosure.

The 3D memory device 103 represents an example of a non-monolithic 3D memory device. The term “non-monolithic” means that the components of 3D memory device 103 (e.g., peripheral circuit and memory array) can be formed separately on different substrates and then joined to form a 3D memory device.

3D memory device 103 can include a second semiconductor structure 140 (e.g., a control structure) and a first semiconductor structure 120 (e.g., a memory structure). 3D memory device 103 can further include an interconnection structure 124 between first and second semiconductor structures 120, 140. A large number of interconnects (e.g., bonding contacts 129, 133 via hybrid bonding) can be formed through the interconnection structure to make direct, short, electrical connections between second semiconductor structure 140 and first semiconductor structure 120, as opposed to the long-distance chip-to-chip data bus on the circuit board, thereby eliminating chip interface delay and achieving high-speed I/O throughput with reduced power consumption. Data transfer between the array of 3D memory strings in first semiconductor structure 120 and the peripheral circuits 125 in second semiconductor structure 140 can be performed through the interconnects (e.g., bonding contacts via hybrid bonding) across the interconnection structure 124. Furthermore, by vertically integrating first and second semiconductor structures 120, 140, the chip size can be reduced, and the memory cell density can be increased. The bonding contacts 129, 133 can be also referred as conductive contacts in the present disclosure.

The relative positions of stacked first and second semiconductor structures 120, 140 and the interconnection structure 124 are not limited. In some implementations, first semiconductor structure 120 can be disposed below second semiconductor structure 140, as illustrated in FIG. 1A. Nevertheless, in such implementations, interconnection structure 124 can be also formed vertically between first and second semiconductor structures 120, 140.

In some implementations, the control structure (e.g., the second semiconductor structure 140) includes peripheral circuits 125. The peripheral circuits 125 can be implemented, for example, with advanced logic processes (e.g., technology nodes of 90 nm, 80 nm, 65 nm, 55 nm, 45 nm, 40 nm, 32 nm, 28 nm, 22 nm, 20 nm, 16 nm, 14 nm, 10 nm, 7 nm, 5 nm, 3 nm, etc.) to achieve high speed. In some implementations, the peripheral circuits in the second semiconductor structure 140 are implemented using complementary metal-oxide-semiconductor (CMOS) technology.

In some implementations, the peripheral circuits 125 include any suitable digital, analog, and/or mixed-signal peripheral circuits used for facilitating the operation of 3D memory device 103. For example, the peripheral circuits 125 can include one or more of a page buffer, a decoder (e.g., a row decoder and a column decoder), a sense amplifier, a driver, a charge pump, a current or voltage reference, or any active or passive components of the circuits (e.g., transistors, diodes, resistors, or capacitors). The peripheral circuits 125 can include transistors 123 formed “on” a substrate 121, in which the entirety or part of the transistors 123 are formed in the substrate 121 and/or directly on the substrate 121. Isolation regions (e.g., shallow trench isolations (STIs)) and doped regions (e.g., source regions and drain regions of the transistors) can be formed in the substrate as well. The transistors 123 are high-speed with advanced logic processes, according to some implementations. In some implementations, the peripheral circuit(s) 125 may further include other circuits compatible with the advanced logic processes including logic circuits, such as processors and programmable logic devices (PLDs), or memory circuits, such as SRAM and DRAM.

In some implementations, second semiconductor structure 140 further includes an interconnect layer to transfer electrical signals to and from the peripheral circuits 125. The interconnect layer can include a plurality of interconnects (also referred to herein as “contacts”), including lateral interconnect lines and vertical interconnect access (VIA) contacts. As used herein, the term “interconnects” can broadly include any suitable types of interconnects, such as middle-end-of-line (MEOL) interconnects and back-end-of-line (BEOL) interconnects. The interconnect layer can further include one or more interlayer dielectric (ILD) layers (also known as “inter-metal dielectric (IMD) layers”) in which the interconnect lines and VIA contacts can form. That is, the interconnect layer can include interconnect lines and VIA contacts in multiple ILD layers. The interconnect lines and VIA contacts in the interconnect layer can include conductive materials including, but not limited to, tungsten (W), cobalt (Co), copper (Cu), aluminum (Al), silicides, or any combination thereof. The ILD layers in the interconnect layer can include one or more dielectric materials including, but not limited to, silicon oxide, silicon nitride, silicon oxynitride, low dielectric constant (low-k) dielectrics, or any combination thereof.

Second semiconductor structure 140 can further include a bonding layer 127. The bonding layer 127 can include bonding contacts 129 and dielectrics electrically isolating the bonding contacts. Bonding contacts 129 can include conductive materials including, but not limited to, W, Co, Cu, Al, silicides, or any combination thereof. The remaining area of bonding layer can be formed with dielectrics including, but not limited to, silicon oxide, silicon nitride, silicon oxynitride, low-k dielectrics, or any combination thereof. Bonding contacts 129 and surrounding dielectrics in the bonding layer 127 can be used for hybrid bonding.

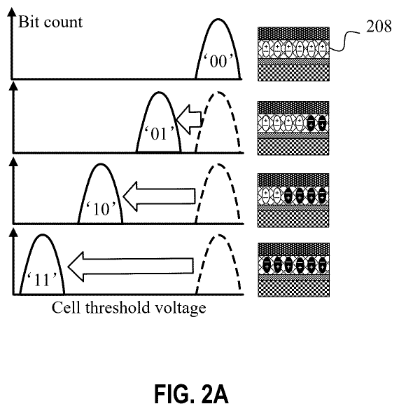

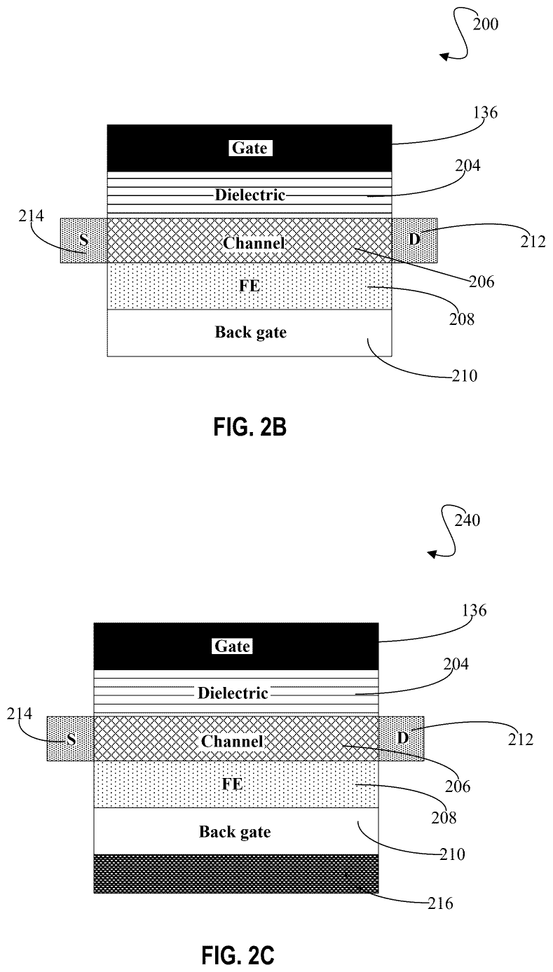

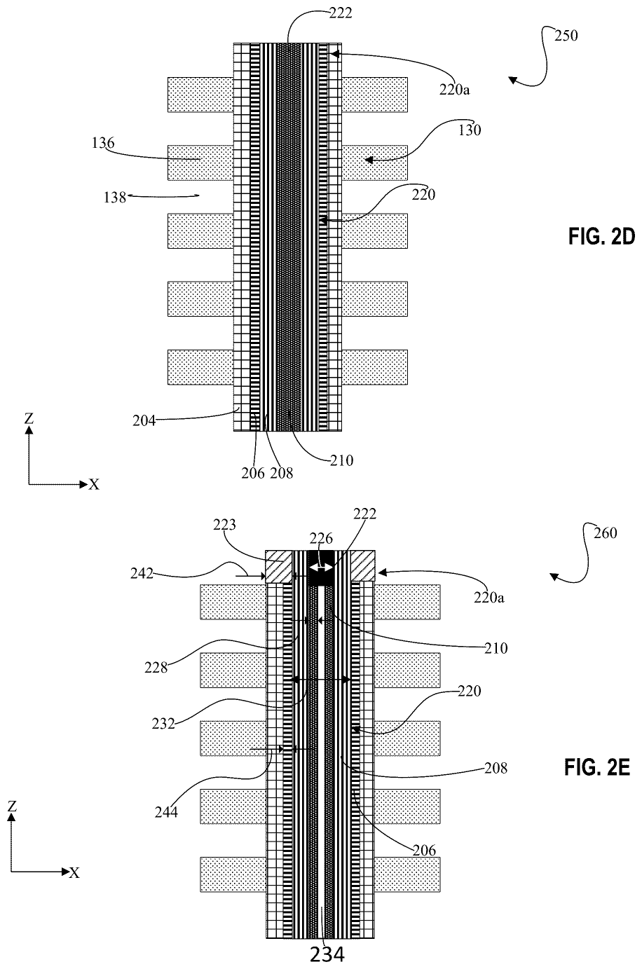

In some implementations, the memory structure (e.g., the first semiconductor structure 120) includes an array of 3D memory array. In some implementations, the first semiconductor structure 120 can be a ferroelectric memory device 103, as described below in further detail in reference to FIGS. 2A-2E.

First semiconductor structure 120 can also include a bonding layer 135 that includes a plurality of bonding contacts 133 and dielectrics electrically isolating bonding contacts. The bonding contacts 133 of first semiconductor structure 120 can include conductive materials including, but not limited to, W, Co, Cu, Al, silicides, or any combination thereof. The remaining area of the bonding layer of the first semiconductor structure 120 can be formed with dielectrics including, but not limited to, silicon oxide, silicon nitride, silicon oxynitride, low-k dielectrics, or any combination thereof. The bonding contacts 133 and surrounding dielectrics in the bonding layer 135 of first semiconductor structure 120 can be used for hybrid bonding.

Second semiconductor structure 140 can be bonded on top of first semiconductor structure 120 in a face-to-face manner. In some implementations, first and second semiconductor structures 120, 140 can be bonded by hybrid bonding (also known as “metal/dielectric hybrid bonding”), which is a direct bonding technology (e.g., forming bonding between surfaces without using intermediate layers, such as solder or adhesives) and can obtain metal-metal bonding and dielectric-dielectric bonding simultaneously.

In some implementations, first semiconductor structure 120 further includes an interconnect layer to transfer electrical signals. The interconnect layer can include a plurality of interconnects, such as MEOL interconnects and BEOL interconnects. The interconnect layer can further include one or more ILD layers in which the interconnect lines and VIA contacts can form. The interconnect lines and VIA contacts in the interconnect layer can include conductive materials including, but not limited to W, Co, Cu, Al, silicides, or any combination thereof. The ILD layers in the interconnect layer can include one or more materials including, but not limited to, silicon oxide, silicon nitride, silicon oxynitride, low-k dielectrics, or any combination thereof.

In some implementations, 3D memory device 103 is a memory device in which memory cells are provided in the form of an array of memory strings (e.g., the ferroelectric memory string 310 of FIG. 3A). As shown in FIGS. 1C, 3D memory device 103 can include a multi-layer stacked structure 130 disposed over substrate 131. In some implementations, substrate 131 includes silicon (e.g., single crystalline silicon, c-Si), silicon germanium (SiGe), gallium arsenide (GaAs), germanium (Ge), silicon-on-insulator (SOI), or any other suitable materials. The substrate 131 can be a thinned substrate with reduced thickness. Multi-layer stacked structure 130 includes alternately stacked isolating layers 138 and conductive layers 136. The conductive layers 136 can also be referred to as first conductive layers 136, gate lines 136, word lines 136 and/or front gates 136 in the present disclosure. The number of the pairs of conductive layers 136 and isolating layers 138 can determine the number of memory cells in 3D memory device 103. As shown, conductive layers 136 and isolating layers 138 can alternate in the vertical direction. In other words, except the ones at the top or bottom of multi-layer stacked structure 130, each conductive layer 136 can be sandwiched between two isolating layers 138, and each isolating layer 138 can be sandwiched between two conductive layers 136. Conductive layers 136 can include conductive materials, for example, including, but not limited to, W, Co, Cu, Al, polysilicon, doped silicon, silicides, or any combination thereof. Each conductive layer 136 can include, for example, a gate electrode surrounded by an adhesive layer and a gate dielectric layer. The gate electrode of conductive layer 136 can extend laterally as a word line, ending at one or more staircase structures 110 of multi-layer stacked structure 130. Isolating layers 138 can include one or more dielectric materials, for example, including, but not limited to, silicon oxide, silicon nitride, silicon oxynitride, or any combination thereof.

The multi-layer stacked structure 130 can have a staircase structure 110. The staircase structure 110 of the 3D memory device can be formed along the Z direction (e.g., a vertical direction) and X direction (e.g., word line direction) with progressively truncated lengths of the conductive layers 136 along the word line direction, as illustrated in FIG. 1C. In some implementations, the isolating layers 138 also have progressively truncated lengths along the word line direction.

3D memory device 103 can further include one or more word line contacts 158 extending in the first semiconductor structure 120 at different depths to connect corresponding conductive layers 136 in the staircase structure 110. The word line contacts 158 can couple out corresponding word lines 136 to a control circuit (e.g., a word line driver). In some implementations, the word line contacts include conductive materials, for example, including, but not limited to, W, Co, Cu, Al, polysilicon, doped silicon, silicides, or any combination thereof.

3D memory device 103 further includes string structures 220 extending in the multi-layer stacked structure 130. The string structures 220 together with corresponding word lines 136 can form a series of ferroelectric memory cells 150 that are stacked vertically along Z direction. In some implementations, as described in further detail below in reference to FIGS. 2D-2E, each of the string structures 220 can include a dielectric layer 204, a channel layer 206, a ferroelectric layer 208, and a back gate 210. The ferroelectric layer 208 can be between the channel layer 206 the back gate 210. The channel layer 206 can be between the word lines 136 and the back gate 210.

In some implementations, the ferroelectric layer 208 includes a ferroelectric material or an anti-ferroelectric material. In some implementations, ferroelectric layer 208 includes one or more dielectric materials, for example, including, but not limited to, Lead Zirconate Titanate (PZT), Strontium Bismuth Tantalate (SBT), Zirconium-doped Hafnium Dioxide (Zr:HfO₂), Aluminum-doped Hafnium Dioxide (Al:HfO₂), Silicon-doped Hafnium Dioxide (Si:HfO₂), Diindium Triselenide (In₂Se₃), Indium Selenide (InSe), or Copper Indium Phosphorus Sulfide (CuInP₂S₆)., or any combination thereof. In some implementations, the channel layer 206 includes amorphous silicon, polycrystalline silicon, monocrystalline silicon, and/or any combination thereof. In some implementations, the dielectric layer 204 includes silicon oxide, silicon nitride, silicon oxynitride, high-k dielectric material (e.g., HfO₂, HfAlO, Al₂O₃), or any combination thereof.

With continued reference to FIGS. 1C, 3D memory device 103 further includes one or more blocking structures 155 extending into multi-layer stacked structure 130 (also called stack structure 130 in the present disclosure). Each of blocking structures 155 can separate one subset of string structures 220 from another subset of string structures 220. In some implementations, blocking structure 155 includes a dielectric material, including, but not limited to, silicon oxide, silicon nitride, silicon oxynitride, or any combination thereof. In some implementations, blocking structure 155 includes a dielectric layer and a conductive layer.

3D memory device 103 includes bit lines 112 coupled to one end of the channel layer 206. Bit lines 112 can be formed penetrating a dielectric layer 184 disposed over the multi-layer stacked structure 130, according to some implementations. In some implementations, bit lines 112 can include bit line contacts 180 formed by forming openings in another dielectric layer disposed between the bit line 112 and the multi-layer stacked structure 130, followed by filling the openings with conductive materials such as W, Co, Cu, Al, Ti, TiN, Ta, TaN, doped silicon, silicides, or any combination thereof, and deposited by CVD, PVD, sputtering, evaporating, plating, or any combination thereof. The bit line contacts 180 can also be referred as a first contact structure 180 in the present disclosure. In some implementations, bit lines 112 can be configured to read data stored in the memory cells of 3D memory device 103.

3D memory device 103 further includes a second contact structure 182 coupled to the back gate 210. The first contact structure 180 and the second contact structure 182 can extend along a same first direction and are isolated from each other by dielectric materials. For example, as illustrated in FIG. 1C, the first contact structure 180 can be in contact with and/or overlapped with the channel layer 206 of the string structure 220, while the second contact structure 182 can be in contact with and/or overlapped with the back gate 210 of the string structure 220. In some implementations, the first contact structure 180 couples out the channel layer to the bit line 112, while the second contact structure 182 couples out the back gate to a back gate (BG) control line 113. Both bit line 112 and the BG control line 113 can extend a same direction (e.g., y direction in FIG. 1D).

In some implementations, the first contact structure 180 is at least part of the bit line 112, and the second contact structure 182 is at least part of the BG control line 113, and both first contact structure 180 and second contact structure 182 can extend along a same direction (e.g., y direction in FIG. 1D).

In some implementations, the first and second contact structure 180, 182 includes conductive materials, including but not limited to W, Co, Cu, Al, TiN, TaN, polysilicon, silicide, or any combination thereof. In some implementations, each of the first and second contact structure 180, 182 includes multiple conductive layers, such as a W layer over a TiN layer. In some implementations, the dielectric layer 184 includes dielectric materials including, but not limited to, silicon oxide, silicon nitride, silicon oxynitride, or any combination thereof.

In some implementations, the first and/or second contact structure 180, 182 are coupled to at least one bonding contact 133 of the first semiconductor structure 120. The first and second contact structure 180, 182 can couple the channel layer 206 and the back gate 210, respectively, to the peripheral circuits in the second semiconductor structure 120 through the bonding contact 133 of the first semiconductor structure 120 and the bonding contact 129 of the second semiconductor structure 140.

FIG. 1D illustrates a top view of the ferroelectric memory device 103 shown in FIG. 1C. As illustrated in FIG. 1D, the ferroelectric memory device 103 can include a plurality of bit lines 112 that are coupled to the channel layers 206 of the ferroelectric memory cells 150, and a plurality of BG control lines 113 that are coupled to the back gates 210 of the ferroelectric memory cells 150. Both the bit lines 112 and the BG control lines 113 can extend along a same direction (e.g., Y direction). In some implementations, the ferroelectric memory device 103 includes a plurality of word line pickup structures 190. The word line pickup structures 190 can be correspondingly coupled to the word line contacts 158 of FIG. 1C to couple out corresponding word lines 136. The word line pickup structure 190 can extend along a direction that is perpendicular to the direction along which the bit lines 112 and the BG control lines 113 extend. For example, the word line pickup structure 190 can extend along X direction of FIG. 1D.

With continued reference to FIG. 1D, the bit lines 112 and the BG control lines 113 can be arranged alternating with each other along x direction and form an array pattern. For example, except for the ones at the edge of the array pattern, each bit line 112 can be sandwiched between two BG control lines 113, and each BG control line 113 can be sandwiched between two bit lines 112. Additionally, adjacent ends of the bit lines 112 and the BG control lines 113 can be arranged in an alternating pattern. For example, the bit lines 112 can include a first bit line 112a, and a second bit line 112b. The BG control lines 113 can include a first BG control line 113a and a second BG control line 113b. The first bit line 112a can extend beyond the adjacent first BG control line 113a along y direction. Similarly, the second bit line 112b can extend beyond the adjacent second BG control line 113b along y direction. This configuration can repeat to form a staggered pattern. In some cases, the staggered pattern may provide larger process window for landing contact structures at the ends of bit lines 112 and the BG control lines 113. Larger process window can improve yield and enhance device reliability with lower short circuit risk.

FIG. 2A illustrates a diagram for a multi-level cell (MLC) in a ferroelectric memory device configured to store 2 bits of data with different threshold voltage levels. Without limiting to any particular theory, ferroelectricity is a property observed in non-centrosymmetric dielectric crystals that show a spontaneous electric polarization, where the direction of polarization can be changed by an externally applied electric field. In a ferroelectric material, some atoms in the unit cell may be misplaced to create a permanent electric dipole due to the distribution of electric charge. A macroscopic manifestation of the charge separation is the surface charge of the ferroelectric material, described by a ferroelectric polarization P. Ferroelectric materials, e.g., Lead Zirconate Titanate (PZT), Strontium Bismuth Tantalate (SrBi₂Ta₂O₉ or SBT), Barium Titanate (BaTiO₃), and PbTiO₃, have a perovskite-type crystal structure, where the cation in the center of the unit cell has two positions, both being stable low-energy states. The two low-energy states correspond to two opposite directions of the electric dipole. Under an external electric field, the cation can move in the direction of the electric field. Thus, by applying an external electric field across the crystal, cation in the unit cell can be moved from one low-energy position to another low-energy position, and the direction of the electric dipole can be flipped if the applied electric field is high enough. As a result, the electric polarization P in the ferroelectric material can be aligned with the direction of the external electric field.

A ferroelectric memory cell (e.g., the ferroelectric memory cell 150 of FIG. 1C) can be a single-level cell (SLC) with two possible memory states that can store one bit of data. For example, the first memory state “0” can correspond to a first range of voltages, and the second memory state “1” can correspond to a second range of voltages. In some implementations, each ferroelectric memory cell 150 is a multi-level cell (MLC) that is capable of storing more than one bit of data in more than two memory states. For example, the MLC can store two bits per cell, three bits per cell (also known as triple-level cell (TLC)), or four bits per cell (also known as a quad-level cell (QLC)). Each MLC can be programmed to support a range of possible nominal storage values. In one example, if each MLC stores two bits of data, then the MLC can be programmed to one of three possible programming levels from an erased state by writing one of three possible nominal storage values to the cell. A fourth nominal storage value can be used for the erased state.

FIG. 2A illustrates an MLC with 2 bits, e.g., including four states, “00,” “01,” “10,” and “11,” representing different configurations of polarization directions. For example, as illustrated in FIG. 2A, the “00” state can correspond to all or substantial all of the electric dipoles in a ferroelectric layer 208 aligning along a first direction and have a first threshold voltage; the “01” state can correspond to a small portion of the electric dipoles aligning along a second direction opposite to the first direction and have a second threshold voltage smaller than the first threshold voltage; the “10” state can correspond to a substantial portion of the electric dipoles aligning along the second direction and have a third threshold voltage smaller than the second threshold voltage; and the “00” state can corresponding to all or substantial all of the electric dipoles aligning along the second direction and have a fourth threshold voltage smaller than the third threshold voltage. It is to be noted that the threshold voltages associated with four different states in a ferroelectric memory cell 150 can be opposite to those of a NAND memory cell (e.g., a device where the cell's threshold voltages depend on an amount of stored charges rather than polarizations of dipoles). For example, in a ferroelectric memory cell 150, the “00” state can correspond to the highest threshold voltage, while “11” state can correspond to the lowest threshold voltage. In contrast, in a NAND memory cell, the “00” state can correspond to the lowest threshold voltage, while the “11” state can correspond to the highest threshold voltage.

FIG. 2B illustrates a schematic two-dimensional (2D) view of an example ferroelectric memory cell 200. FIG. 2C illustrates a schematic 2D view of another example ferroelectric memory cell 240. The example ferroelectric memory cell 200, 240 can be the ferroelectric memory cell 150 of FIG. 1C.

As illustrated in FIG. 2B, in some implementations, the ferroelectric memory cell 200 includes a first conductive layer 136, a first dielectric layer 204 in contact with the first conductive layer 136, a channel layer 206 in contact with the first dielectric layer 204, a ferroelectric layer 208 in contact with the channel layer 206, and a second conductive layer 210 in contact with the ferroelectric layer 208. As noted above, the first conductive layer 136 can be referred to as gate line, word line, front gate, or conductive layer in the present disclosure. The channel layer 206 can be between the first conductive layer 136 and the second conductive layer 210, and the ferroelectric layer 208 can be between the channel layer 206 and the second conductive layer 210. The second conductive layer 210 can be referred to as back gate, or back gate line in the present disclosure. In some examples, the back gate line in the present disclosure can correspond to the back gate layer in a string structure as described below in reference to FIGS. 2D-2E, while the back gate can correspond to a part of the back gate line that is associated with a single ferroelectric memory cell.

In some implementations, the second conductive layer 210 includes at least one of a metallic material or polysilicon. For example, the second conductive layer 210 can include, but not limited to W, Co, Cu, Al, TiN, TaN, polysilicon, silicide, or any combination thereof. In some implementations, the second conductive layer 210 includes multiple conductive layers, such as a W layer over a TiN layer. The second conductive layer 210 can also be referred to as back gate in the present disclosure.

In some implementations, the ferroelectric layer 208 includes at least one of Lead Zirconate Titanate (PZT), Strontium Bismuth Tantalate (SBT), Zirconium-doped Hafnium Dioxide (Zr:HfO₂), Aluminum-doped Hafnium Dioxide (Al:HfO₂), Silicon-doped Hafnium Dioxide (Si:HfO₂), Diindium Triselenide (In₂Se₃), indium Selenide (InSe), or Copper Indium Phosphorus Sulfide (CuInP₂S₆). Without limiting to any particular theory, the ferroelectric layer 208 can be made of a ferroelectric material that has spontaneous electric polarization that can be reversed by an applied electric field. In some implementations, the first dielectric layer 204 includes dielectric materials including, but not limited to, silicon oxide, silicon nitride, silicon oxynitride, or any combination thereof.

In some implementations, a first end (e.g., source terminal) of the channel layer 206 is coupled to a source line 214, and a second end (e.g., drain terminal) of the channel layer 206 is coupled to a bit line 212. The bit line 212 can be, e.g., the bit line 112 of FIGS. 1C and 1D. The source line 214 can be connected to a doped source line region in a substrate (e.g., substrate 131 of FIG. 1C), e.g., from where an array common source (ACS) can be formed.

In some implementations, as illustrated in FIG. 2C, the ferroelectric memory cell includes a second dielectric layer 216 in contact with the second conductive layer 210, and the second conductive layer 210 is between the second dielectric layer 216 and the ferroelectric layer 208. In some implementations, the second dielectric layer 216 includes the dielectric material including, but not limited to, silicon oxide, silicon nitride, silicon oxynitride, or any combination thereof.

FIG. 2D illustrates a side view of example ferroelectric memory cells arranged in series in an example ferroelectric memory device 250. FIG. 2E illustrates a side view of another example ferroelectric memory cells arranged in series in another example ferroelectric memory device 260. As described above in reference to FIG. 1C, the ferroelectric memory device 250 includes a multi-layer stacked structure 130 (also called stack structure 130 for simplicity) of first conductive layers 136 and isolating layers 138 alternating with each other along a first direction (e.g., Z direction). The ferroelectric memory device 250 further includes a string structure 220 extending in the stack structure 130 along the Z direction. In some implementations, the string structure 220 includes a dielectric layer 204, a channel layer 206 surrounded by the dielectric layer 204 (also called first dielectric layer 204 in the present disclosure), a ferroelectric layer 208 surrounded by the channel layer 206, and a second conductive layer 210 surrounded by the ferroelectric layer 208. As illustrated in FIG. 2C, the channel layer 206 is between at least one of the first conductive layers 136 and the second conductive layer 210 (e.g., along x direction or, word line direction), and the ferroelectric layer 208 is between the channel layer 206 and the second conductive layer 210 along the same direction.

In some implementations, as illustrated in FIG. 2E, the string structure 220 includes an inner layer 234 surrounded by the second conductive layer 210. The inner layer 234 can be the second dielectric layer 216 of FIG. 2C. The inner layer 234 can include dielectric materials including, but not limited to, silicon oxide, silicon nitride, silicon oxynitride, or any combination thereof.

With continued reference to FIG. 2E, in some implementations, the ferroelectric memory device 260 includes a first plug 222 at a first end 220a of the string structure 220. The first plug 222 can be coupled to the second conductive layer 210 of the string structure 220, and a size 226 of the first plug 222 along the second direction (e.g., x direction) can be greater than a size 228 of the second conductive layer 210 along the second direction. The size 226 of the first plug 222 can be its outer diameter or width along x direction. The size 228 of the second conductive layer 210 can be its width along x direction. With a greater size, the first plug 222 can provide a larger surface area, enabling a wider processing window for landing the second contact structure 182 (e.g., as illustrated in FIG. 1C) on the first plug 222 to couple out the second conductive layer 210 to control circuits.

In some implementations, the size 226 of the first plug 222 along the second direction (e.g., x direction, or word line direction) is smaller than a size 232 of the ferroelectric layer 208 along the second direction. The size 232 of the ferroelectric layer 208 can be its outer diameter or width along x direction. Therefore, the first plug 222 may not be in contact with the channel layer 206.

In some implementations, the ferroelectric memory device 260 includes a second plug 223 at the first end 220a of the string structure 220. The second plug 223 can at least partially surround the first plug 222 but spaced apart from the first plug 222. For example, the second plug 223 can be separated from the first plug 222 by the ferroelectric layer 208. In some implementations, the second plug 223 has a hollow cylinder shape.

The second plug 223 can be coupled to the channel layer 206 of the string structure 220, and a size 242 of the second plug 223 along the second direction (e.g., x direction) can be greater than a size 244 of the channel layer 206 along the second direction (e.g., x direction). The size 242 of the second plug 223 can be its width along x direction. The size 244 of the channel layer 206 can be its width along x direction. With a greater size, the second plug 223 can provide a larger surface area, enabling a wider processing window for landing the first contact structure 180 (e.g., as illustrated in FIG. 1C) on the second plug 223 to couple out the channel layer 206 to control circuits.

The first and second plug 222, 223 can include the same or different conductive materials. In some implementations, the first and/or second plug 222, 223 is made of a conductive material including, but not limited to W, Co, Cu, Al, TiN, TaN, polysilicon, silicide, or any combination thereof. In some implementations, the first and/or second plug 222, 223 includes multiple conductive layers, such as a W layer over a TiN layer.

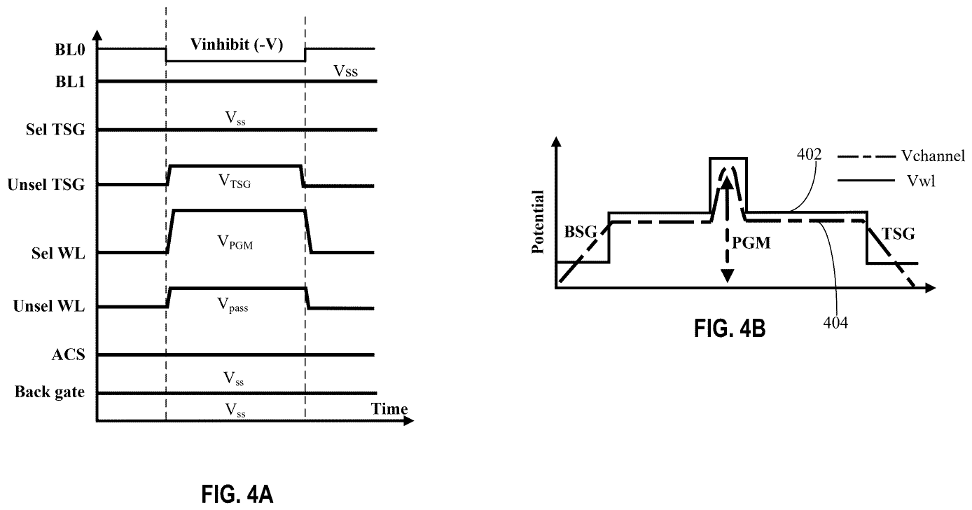

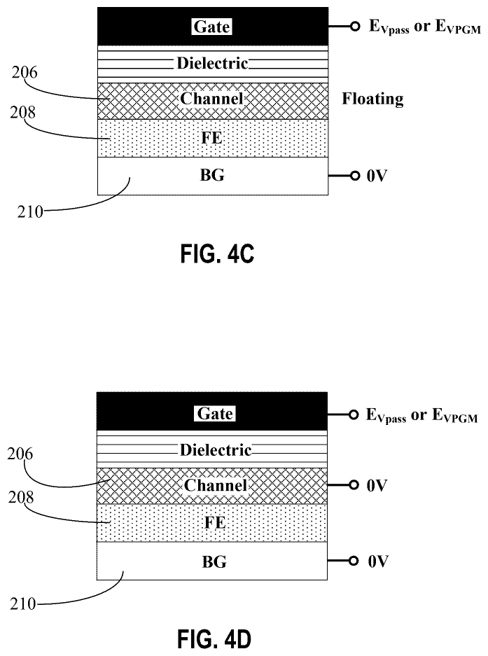

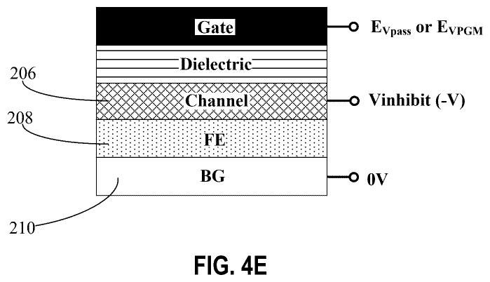

FIG. 3A illustrates a schematic circuit diagram of an example ferroelectric memory array 300 during a program operation. FIG. 3B illustrates a three-dimensional schematic circuit diagram of an example ferroelectric memory array 380 during the program operation. The example ferroelectric memory array 380 can be substantially similar to the example ferroelectric memory array 300. FIG. 4A illustrates an example signal diagram for programming the ferroelectric memory array 300. FIG. 4B illustrates an example channel potential distribution in a selected memory string during the program operation. FIG. 4C illustrates a ferroelectric memory cell in a selected memory string during the program operation. FIG. 4D illustrates an unselected ferroelectric memory cell in an unselected memory string during the program operation. FIG. 4E shows another unselected ferroelectric memory cell corresponding to a second bit line during the program operation. For ease of description, reference will be made to FIGS. 3-4E when describing the program operation for the ferroelectric memory array 300.

The ferroelectric memory array 300 can be part of a ferroelectric memory device (e.g., the first semiconductor structure 102 of FIGS. 1A and 1B, the first semiconductor structure 120 of FIG. 1C, the ferroelectric memory device 250 of FIG. 2D, or the ferroelectric memory device 260 of FIG. 2E).

As illustrated in FIG. 3A, the ferroelectric memory array 300 includes a plurality of memory strings 310, each memory string 310 having a plurality of stacked memory cells (e.g., the ferroelectric memory cells 302). The ferroelectric memory cell 302 can be the ferroelectric memory cell 150 of FIG. 1C, the ferroelectric memory cell 200 of FIG. 2B, or the ferroelectric memory cell 240 of FIG. 2C. Each memory string 310 can include one or more string structures (e.g., string structure 220 of FIGS. 1C, 2D and 2E). In some implementations, each string structure (e.g., string structure 220 of FIGS. 1C, 2D and 2E) has a back gate line (e.g., BG1, . . . , or BGn). The back gate line can be the back gate 210 of FIGS. 1A and 2B-2E. The back gate line can extend in the same direction as the channel layer 206 of string structure 220. The back gate line can be applied with a back gate voltage (e.g., Vss) during a program operation. Vss in the present disclosure can be a ground level (e.g., 0V), or about 0V (e.g., a value between −0.2V and 0.2V, a value between −0.1V and 0.1V, or a value between−0.05V and 0.05V).

In some implementations, each memory string 310 also includes at least one field effect transistor (e.g., MOSFET) at each end, which is controlled by a bottom select gate (BSG) and a top select gate (TSG), respectively. And the two respective transistors are referred to as bottom and top select transistors 306 and 304. The vertically stacked ferroelectric memory cells 302 can be controlled by the word lines (e.g., WL1, . . . , WLn). The drain terminal of the top select transistor 304 can be connected to the bit line (e.g., BL0, . . . , BLn), and the source terminal of the lower select transistor 306 can be connected to a doped source line region, e.g., from where an array common source (ACS) can be formed. In some implementations, multiple array common sources ACS can be electrically connected with each other and shared by the memory strings 310 in an entire memory block. Thus, in some implementations, the array common source ACS is also referred to as the common source line or source line. In this example, the TSG and BSG need to be addressed coordinately to support reading and/or programing (e.g., writing) operations of a target memory cell (e.g., the ferroelectric memory cell 302-1).

In the ferroelectric memory array 300, read and write operations can be performed in a memory page, which includes memory cells sharing the same word line. In some implementations, the ferroelectric memory cell 302 is a single level cell (SLC), which can be programmed to a logic state of “0” or “1.” In some implementations, the ferroelectric memory cell 302 is a MLC with 2bites, which can be programmed to a logic state of “00”, “01,” “10,” and “11,” as shown in FIG. 2A.

In some implementations, a selected ferroelectric memory cell 302 can be programmed during a program operation. The selected ferroelectric memory cells can be the memory cells that are coupled to the selected word line WL1. For example, the selected memory cells can include, without limitation to, the ferroelectric memory cells 302-1, 302-3 in FIG. 3A. However, not all selected memory cells are to be programmed in the present example of the program operation shown in FIG. 3A. As described in further details below, because the ferroelectric memory cell 302-3 is coupled to the bit line BLn that is applied with an inhibit voltage, the ferroelectric memory cell 302-3 may not be programmed in the present program operation. In some examples, the selection of memory cells to receive programming pulses depends on whether the initial data loaded into a data register is 0 or 1, as well as whether the ferroelectric memory cell has been successfully programmed to its target state. In the subsequent discussions, the selected ferroelectric memory cells 302-1 will be used as an example of the ferroelectric memory cell that is selected to be programmed. The selected ferroelectric memory cell 302-1 can also be referred to as the first ferroelectric memory cell in the present disclosure.

As illustrated in FIGS. 3A and 4A, in some implementations, performing a program operation on the selected ferroelectric memory cell 302-1 includes applying a program voltage Vpgm to a first word line (e.g., WL1 of FIG. 3A, or sel WL of FIG. 4A) coupled to the selected ferroelectric memory cell 302-1; applying a pass voltage Vpass to a second word line (e.g., WL0, WL2, . . . and/or WLn of FIG. 3A, or unsel WL of FIG. 4A) coupled to a second ferroelectric memory cell. The second ferroelectric memory cell can be an unselected ferroelectric memory cell. The unselected ferroelectric memory cells can be the memory cells that are coupled to the unselected word lines (e.g., WL2, . . . WLn). For example, the unselected ferroelectric memory cell can include, without limitation to, the unselected ferroelectric memory cells 302-n, 302-n2 of FIG. 3A. The pass voltage can be smaller than the program voltage Vpgm such that it is insufficient to program unselected ferroelectric memory cells. In some implementations, the program voltage is between 5V and 10V, and the pass voltage is between 3V and 8V.

The program operation can further include applying a first voltage (e.g., Vss) to a selected top select gate (TSG); and applying a second voltage (e.g., Vcon of FIG. 3A, or V_{TSG} of FIG. 4A) greater than the first voltage to an unselected TSG. The selected TSG (e.g., TSG1 of FIGS. 3A and 3B) can be coupled to one or more selected TSG transistors (e.g., the TSG transistor 304-1, 304-2 of FIGS. 3A and 3B). The unselected TSG (e.g., TSG2 of FIG. 3B) can be coupled to one or more unselected TSG transistors (e.g., the TSG transistor 304-3, 304-4 of FIG. 3B).

The selected TSG transistor 304-1, 304-2 can be configured to be turned off by the first voltage (e.g., Vss), while the unselected TSG transistor 304-3, 304-4 can be configured to be turned on by the second voltage. For example, the first voltage can be smaller than a threshold voltage of a TSG transistor, while the second voltage can be greater than the threshold voltage of the TSG transistor. In some implementations, the first voltage is zero. In some implementations, the first voltage is in a range of 0V to 0.5V. In some implementations, the second voltage is between 0.5V and 10V. As described with further detail in reference to FIG. 4B, as the selected TSG transistors 304-1, 304-2 are turned off, the channel layers 206 in the selected memory string 310-1(e.g., formed by the string structures ST1 and ST2 of FIG. 3B) can be floating. Additionally, as the unselected TSG transistors 304-3, 304-4 are turned on, the channel layer 206 in the unselected memory string 310-2 (e.g., formed by the string structures ST3, ST4 of FIG. 3B) can be connected to corresponding bit lines (e.g., BL1, BLn of FIG. 3B) and/or a source line (e.g., ACS of FIG. 3B).

In some examples, the voltages applied to the selected TSG and the unselected TSG in a ferroelectric memory cell described in the present disclosure can be opposite to the voltages applied to a NAND memory cell that uses trapped charges for storing user data. For example, in the NAND memory cell that uses trapped charges for storing user data, during a program operation, the selected TSG transistor can be switched on, while the unselected TSG transistor can be switched off.

The program operation can further include applying a back gate voltage to a first back gate line coupled to the selected ferroelectric memory cell and a second back gate line coupled to an unselected ferroelectric memory cell; and applying a source line voltage to a source line coupled to the selected and unselected ferroelectric memory cells. The back gate voltage can be Vss (e.g., 0V). The first back gate line can be the back gate BG2 in FIG. 3A, and the second back gate line can be any one of BG0, BG1, . . . , and BGn in FIG. 3A. In some examples, the second ferroelectric memory cell is the ferroelectric memory cell 302-n2 of FIG. 3A, and the second back gate line can be BGn of FIG. 3A. In some examples, the second ferroelectric memory cell is the ferroelectric memory cell 302-n of FIG. 3A, and the second back gate line can be the same as the first back gate line, e.g., BG2. The source line voltage can be Vss.

As illustrated in FIG. 4B, in a selected memory string (e.g., selected memory string 310-1 of FIG. 3B), as the selected TSG transistor (e.g., 304-1, 304-2 of FIG. 3B) can be turned off, the channel layers 206 in the selected memory string 310-1 can be floating. As the program voltage Vpgm is applied to the selected ferroelectric memory cell 302-1 and the pass voltage Vpass is applied to the unselected ferroelectric memory cells, the channel potential can be boosted in response to the applied program voltage and pass voltage. For example, as shown in FIG. 4B, the voltages applied to the word lines (e.g., the sel WL and unsel WL of FIG. 4A) can be indicated by a first curve 402, while the boosted channel potential can be indicated by a second curve 404. The channel potential can approach the applied voltage in the word lines after boosting. Therefore, in the selected ferroelectric memory cell 302-1, the channel potential can be close to the program voltage Vpgm applied to the selected word line WL1, while in the unselected ferroelectric memory cells, the channel potential can be close to the pass voltage Vpass applied to the unselected word lines WL0, WL2, . . . , WLn.

The boosted channel potential can be used to program the selected ferroelectric memory cell 302-1. As illustrated in FIG. 4C, for the selected ferroelectric memory cell 302-1 in the selected memory string 310-1, the channel potential can be close to Vpgm, and the back gate 210 is connected to a low voltage (e.g., 0V). The electric field formed between the channel layer 206 and the back gate 210 can be sufficient to reverse the polarization orientations of at least some electric dipoles in the ferroelectric layer 208, thereby programming the selected ferroelectric memory cell 302-1 to a target state. For an unselected ferroelectric memory cell in the selected memory string 310-1, the channel potential can be close to Vpass, which is smaller than Vpgm. Although the back gate 210 for the unselected ferroelectric memory cell in the selected memory string 310-1 is also connected to a low voltage (e.g., 0V), the electric field formed based on Vpass may be insufficient to overcome the coercive field of ferroelectric material in the ferroelectric layer 208. Therefore, the unselected ferroelectric memory cells in the selected memory string 310-1 may not be programmed.

As illustrated in FIG. 4D, for an unselected ferroelectric memory cell (e.g., 302-m of FIG. 3B) in the unselected memory string (e.g., 310-2 of FIG. 3B), as the unselected TSG transistor 304-4 is turned on, the channel layers 206 in the unselected ferroelectric memory cell 302-m in the unselected memory string 310-2 can be biased to a bit line voltage (e.g., 0V). As the back gate 210 can be also biased to 0V, the electric field between the channel layer 206 and the back gate 210 can be zero or close to zero. As a result, the ferroelectric layer 208 in the unselected ferroelectric memory cell 302-m in the unselected memory string 310-2 can experience no electric field or near-zero electric field. Therefore, the channel layers 206 in the unselected ferroelectric memory cell 302-m can shield the ferroelectric layer 208 from the high electric field caused by Vpgm or Vpass, thereby reducing or eliminating the risk of polarization reversal during the program operation. Accordingly, program disturb can be greatly improved.

In some implementations, referring back to FIG. 4A, the program operation includes applying a first bit line voltage (e.g., Vss) to a first bit line (e.g., BL1 of FIGS. 3A, 3B and 4A) coupled to the first ferroelectric memory cell 302-1; and applying a second bit line voltage to a second bit line coupled to a third ferroelectric memory cell. The second bit line voltage (e.g., Vinhibit in FIG. 3A) is smaller than the first bit line voltage (e.g., Vss). The third ferroelectric memory cell can be a selected ferroelectric memory cell that has been programmed. For example, the third ferroelectric memory cell can be the ferroelectric memory cell 302-3 of FIGS. 3A and 3B. The second bit line can be an unselected bit line (e.g., BLn of FIGS. 3A and 3B) that is coupled to the third ferroelectric memory cell 302-3.

Referring to both FIGS. 4A and 4E, in some implementations, the second bit line voltage is a negative voltage, such that voltage drop between the selected TSG voltage (e.g., Vss) and the second bit line voltage (e.g., the inhibit voltage Vinhibit that is negative) can switch on the corresponding TSG transistors (e.g., TSG transistor 304-2 in FIGS. 3A and 3B). As the TSG transistors 304-2 are turned on, the channel layer 206 of the third ferroelectric memory cell 302-3 can be biased to the negative inhibit voltage Vinhibit (e.g., −V) applied to the bit line BLn. This negative inhibit voltage can eliminate or reduce the risk of the channel layer 206 of the third ferroelectric memory cell 302-3 being boosted by the program voltage Vpgm. Therefore, the third ferroelectric memory cell 302-3 is less likely to be inadvertently programed or disturbed during the program operation.

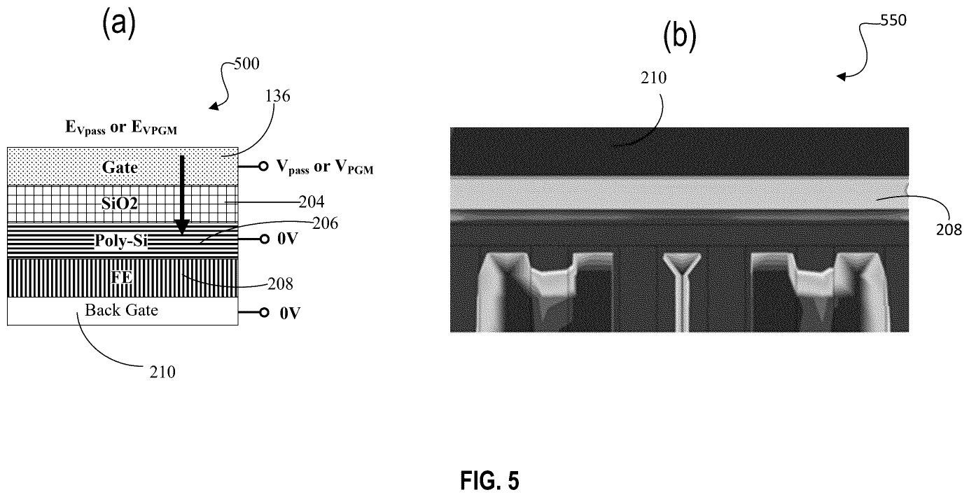

FIG. 5 illustrates an example simulated potential distribution in an unselected ferroelectric memory cell 500 in an unselected memory string. Diagram (a) of FIG. 5 illustrates a 2D view of the unselected ferroelectric memory cell 500, which is the same or substantially similar to FIG. 4D. Diagram (b) of FIG. 5 illustrates the simulated potential distribution graph 550 in the ferroelectric memory cell 500 shown in diagram (a) of FIG. 5. Different shade in the graph 550 can represent different potential levels, with a lighter shade can indicating a lower potential. The ferroelectric memory cell 500 can be, e.g., the ferroelectric memory cell 302-m of FIG. 3B.

As noted above, in an unselected memory string (e.g., 310-2 of FIG. 3B), the unselected TSG transistor (e.g., 304-3, 304-4 of FIG. 3B) can be turned on. Therefore, the channel layer 206 in the ferroelectric memory cell 500 can be biased to 0V. During the program operation, the back gate 210 of the ferroelectric memory cell 500 can also be biased to 0V. Therefore, the ferroelectric layer 208 between the channel layer 206 and the back gate 210 can experience a low electric field or zero electric field. As shown in diagram (b) of FIG. 5, the simulated potential distribution shows a low potential level in the ferroelectric layer 208, reducing the risk of reversing polarization orientations in the ferroelectric layer 208. Therefore, the program disturb can be significantly approved by the implementations of the present disclosure.

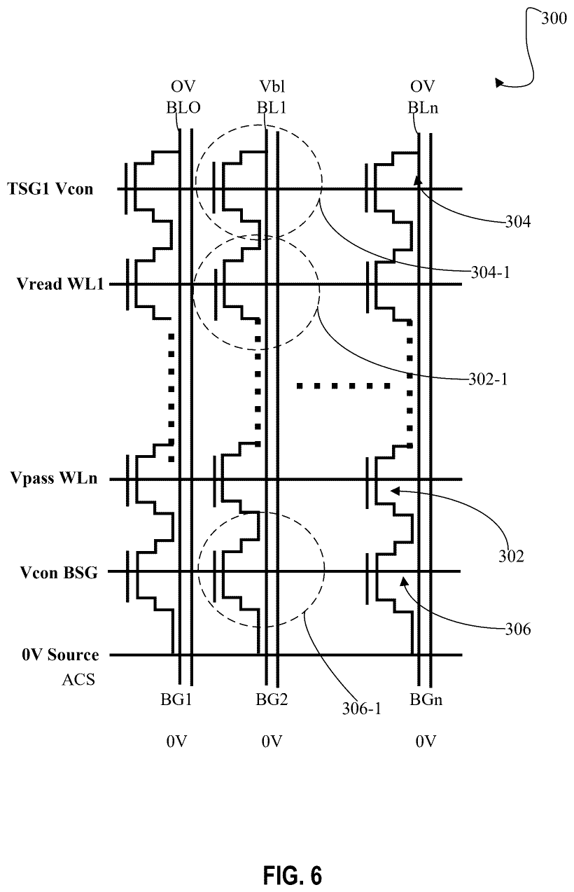

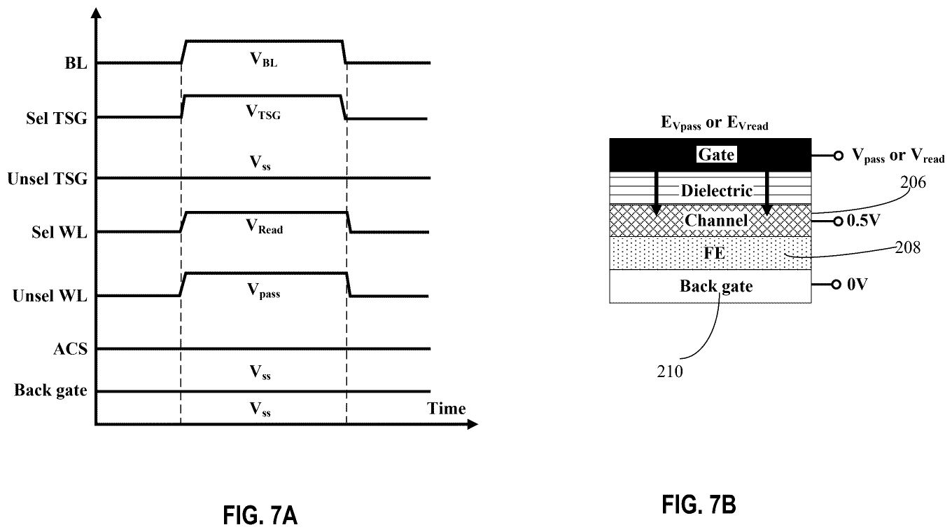

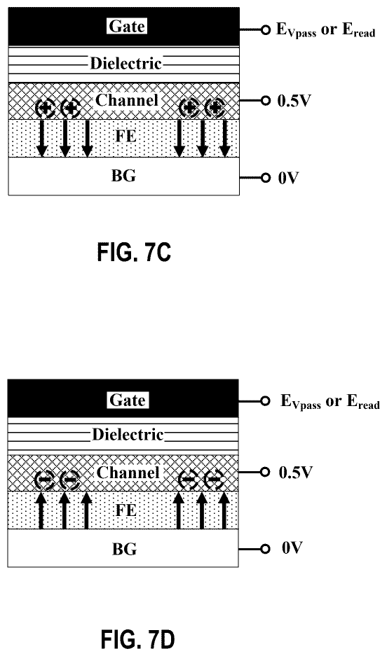

FIG. 6 illustrates a schematic circuit diagram of the example ferroelectric memory array 300 of FIG. 3A during a read operation. FIG. 7A illustrates an example signal diagram for reading the example ferroelectric memory array 300. FIG. 7B illustrates a ferroelectric memory cell in a selected memory string 310-1 during the read operation. FIGS. 7C and 7D illustrate the ferroelectric memory cell of FIG. 7B with a high voltage threshold and a low voltage threshold, respectively. For ease of description, reference will be made to FIGS. 6-7D when describing the read operation for the ferroelectric memory array 300.

As illustrated in FIG. 6, in some implementations, initially, the ferroelectric layer (e.g., the ferroelectric layer 208 of FIGS. 2B-2E) in each ferroelectric memory cell 302 can have zero polarization and can be set or reset to logic state “11” or “00.” At the logic state of “11,” the ferroelectric memory cell 302 can be set to a lower threshold voltage Vth_L, and the current flowing through the ferroelectric memory cells 302 between the source terminal (connected to the array common source ACS) and the drain terminal (connected to the bit lines) can be at a higher level for a given bias on the word line. At the logic state of “00,” the ferroelectric memory cells 302 can be reset to the higher threshold voltage Vth_H, (e.g., Vth_H>Vth_L) and the current flowing through the ferroelectric memory cells 302 between the source terminal and the drain terminal can be at a lower level for a given bias on the word line. By measuring (e.g., reading) the current that flows through the source and drain terminals of a selected ferroelectric memory cell 302-1, the threshold voltage Vth_H or Vth_L and thereby the logic state (or programmed data) of the ferroelectric memory cell 302 can be determined accordingly. In some implementations, the higher and lower threshold voltages Vth_H and Vth_L can be in a range between about −3V to about 3V.

In some examples, as illustrated in FIGS. 6 and 7A, to read the data in the selected ferroelectric memory cell 302-1, which is coupled to the word line WL1 and the bit line BL1, the corresponding TSG and the BSG of a selected memory string 310-1 can be applied with a top select gate voltage Vtsg (e.g., Vcon in FIG. 6, or V_{TSG} in FIG. 7A) and a bottom select gate voltage Vbsg (e.g., Vcon in FIG. 6) to switch on corresponding top select transistors (e.g., 304-1 of FIG. 6) and lower select transistors (e.g., 306-1 of FIG. 6). In this example, a current path through the ferroelectric memory cell 302-1 can be established for the selected memory string 310-1. The current flowing through the selected memory string 310-1 can be detected from the bit line BL1 and the array common source ACS that are coupled to the selected memory cell 302-1.

In order to read the storage data in the target memory cell (e.g., the ferroelectric memory cell 302-1), the TSG of unselected memory strings can be applied with an off voltage (e.g., 0V) to switch off a corresponding top select transistor. The off voltage can be smaller than the top select gate voltage Vtsg. A current path between the unselected memory string and bit line can thereby be disconnected. In this example, storage data can be read from one memory cell at a time.

In some implementations, the TSGs and BSGs of the unselected memory strings (e.g., 310-2 of FIG. 3B) can also be applied with the top select gate voltage Vtsg and the bottom select gate voltage Vbsg, respectively, to switch on the corresponding top select transistors 304 and lower select transistor 306, and to establish conductive paths between the bit lines and the unselected memory strings. In this example, data stored in the ferroelectric memory cells 302 in the same memory page can be measured simultaneously at respective bit lines by applying the reading voltage Vread at the shared word line WL1. In this example, storage data can be read simultaneously from all the memory cells 302 in one memory page.

With continued reference to FIGS. 6 and 7A, to read the selected ferroelectric memory cell 302-1 in the selected memory string 310-1, a selected word line (e.g., word line WL1) can be applied with the read voltage Vread, while other word lines that are not selected can be applied with a pass voltage Vpass. The pass voltage Vpass can be higher than the highest threshold voltage of all the ferroelectric memory cells 302 such that all the other ferroelectric memory cells 302 on the selected memory string 310-1 can be fully switched on. The read voltage Vread applied on the selected word line WL1 can be adjusted for sensing (e.g., reading or measuring) the threshold voltage of the selected ferroelectric memory cell 302-1. In some implementations, the read voltage Vread can have a value in between the lower and higher threshold voltages Vth_L and Vth_H, e.g., Vth_L<Vread<Vth_H. In some implementations, the read voltage is between −5V and 5V.

During the current measurement, a bit line voltage V_{BL} can be applied to the bit line BL1, while the array common source ACS can be grounded (e.g., kept at 0V). To avoid disturbing the polarization of the ferroelectric layer 208 in the ferroelectric memory cell 302, the read voltage Vread and the pass voltage Vpass should be less than the coercive voltage V. For example, in some implementations, if the coercive voltage Vc=5.0V, the read voltage Vread and the pass voltage Vpass can range between about −5.0V and about 5.0V. The bit line voltage V_{BL} applied to the bit line for sensing (or reading) the current can be low enough without causing significant potential change in a channel layer 206. The resistance of the selected ferroelectric memory cell 302-1 can be extracted from the measured current and the bit line voltage V_{BL}. In some implementations, the bit line voltage V_{BL} can be in a range between about 0V to about 5V. In some implementations, the bit line voltage V_{BL} is 0.5V.

During the read operation, a back gate 210 voltage (e.g., Vss) is applied to the back gate 210 coupled to the selected ferroelectric memory cell (e.g., ferroelectric memory cell 302-1 of FIG. 6). As illustrated in FIG. 7B, the ferroelectric layer 208 is between the channel layer 206 and the back gate 210. The channel layers 206 in the selected memory string 310-1 can be biased to the bit line voltage as the selected TSG transistor (e.g., 304-1, 304-2 of FIG. 3B) can be turned on. The channel layer 206 can shield the ferroelectric layer 208 from the high electric field generated by the read voltage Vread or the pass voltage Vpass applied to the word lines. Therefore, the ferroelectric layer 208 may only experience a low electric field or a near-zero electric field from the voltage difference between the channel layer 206 and the back gate 210. This low electric field reduces the risk of reversing the polarization state of the ferroelectric layer 208, thereby significantly reducing or eliminating read disturb.

As illustrated in FIGS. 7C and 7D, without limiting to any particular theory, different polarization states of the ferroelectric layer 208 can generate varying electric fields, and these electric fields affect the threshold voltages (Vt) of the ferroelectric memory cell 302. By applying different read voltages, the variations in the threshold voltages (Vt) of the ferroelectric memory cell 302 can be distinguished, allowing the stored data to be read.

For example, as illustrated in FIG. 7D, if the selected ferroelectric memory cell 302-1 is at the logic state of “11” having the lower threshold voltage Vth_L, the selected ferroelectric memory cell 302-1 can be switched on when applying a read voltage (e.g., Vread that is between Vth_L and Vth_H) on the word line WL1. Then, the top and lower select transistors 304-1 and 306-1, and all the memory cells 302 in the selected memory string 310-1 are switched on. Higher level of current flows between the bit line BL1 and the array common source ACS with a conductive path having a lower resistance. By measuring the current at bit line BL1, the logic state of the selected ferroelectric memory cell 302-1 can be determined.

As illustrated in FIG. 7C, if the selected ferroelectric memory cell 302-1 is at the logic state of “00” with the higher threshold voltage Vth_H, the selected ferroelectric memory cell 302-1 can be switched off when applying the same read voltage on the word line WL1 as used in the example above. Under this operation condition, even though the top and lower select transistors 304-1 and 306-1, and all the other memory cells 302 of the selected memory string 310-1 are switched on, the selected ferroelectric memory cell 302-1 is switched off. Lower level of current flows between the bit line BL1 and the array common source ACS with a conductive path having a higher resistance. Therefore, the logic states of “00” and “11” of the selected ferroelectric memory cell 302-1, based on threshold voltages of Vth_H and Vth_L, can be determined accordingly. It is to be noted while the ferroelectric memory cell has been described to be a MLC with 2 bits in reference to FIGS. 7C and 7D, the ferroelectric memory cell can be a SLC, or a MLC with 3 or more bits.

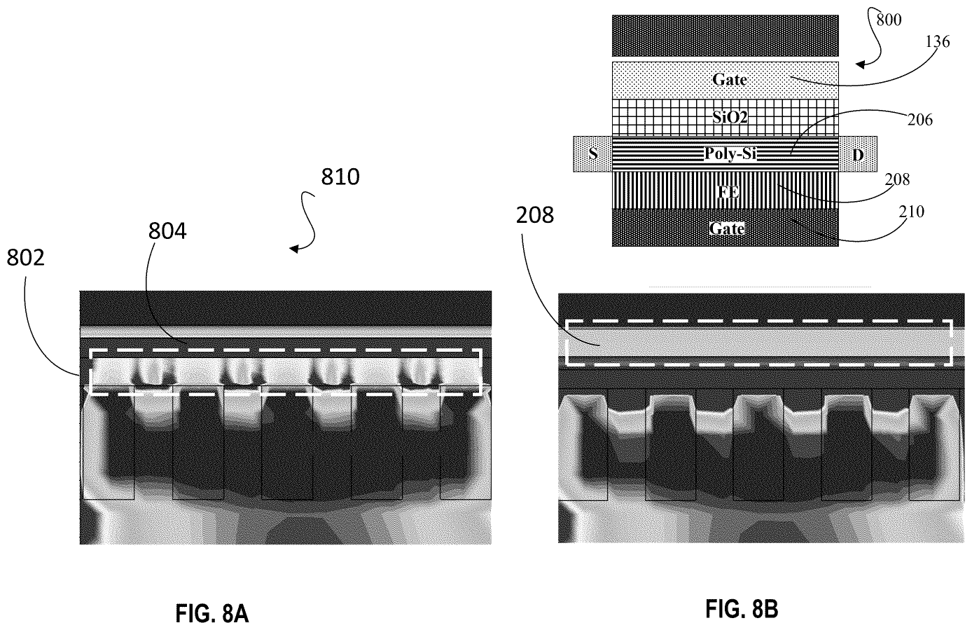

FIG. 8A illustrates an example simulated potential distribution in a reference ferroelectric memory cell 810 that does not include a back gate. FIG. 8B illustrates an example simulated potential distribution in an example ferroelectric memory cell 800 according to one or more implementations of the present disclosure. Different shade in FIGS. 8A and 8B can represent different potential levels, with lighter shade indicating a lower potential.

As illustrated in FIG. 8A, the reference ferroelectric memory cell 810 that does not include back gate can have a ferroelectric layer 802 and a gate layer 804 (e.g., a word line) that are in contact with or close to each other. Because of the read voltages and the pass voltages applied in the gate layer 804, the ferroelectric layer 802 can experience a high electric field. The high electric field may be sufficient to reverse the polarization state of at least some electric dipoles of the ferroelectric layer 802, thereby causing read disturb.

In contrast, as illustrated in FIG. 8B, ferroelectric memory cell 800 has a back gate 210 according to one or more implementations of the present disclosure. Additionally, the channel layer 206 in the ferroelectric memory cell 800 can be between the front gate 136 and the ferroelectric layer 208. During a read operation, the back gate 210 can be biased at 0V. The channel layer 206 can be biased at a bit line voltage, e.g., 0.5V. The channel layer 206 can shield the ferroelectric layer 208 from the high electric fields generated by the read voltage Vread or the pass voltage Vpass applied to the word lines. Therefore, the ferroelectric layer 208 between the channel layer 206 and the back gate 210 can experience a low electric field or zero electric field. Comparing FIG. 8B to FIG. 8A, the simulated potential distribution shows a lower potential level in the ferroelectric layer 208 of the ferroelectric memory cell 800. Therefore, the read disturb can be significantly approved by the implementations of the present disclosure.

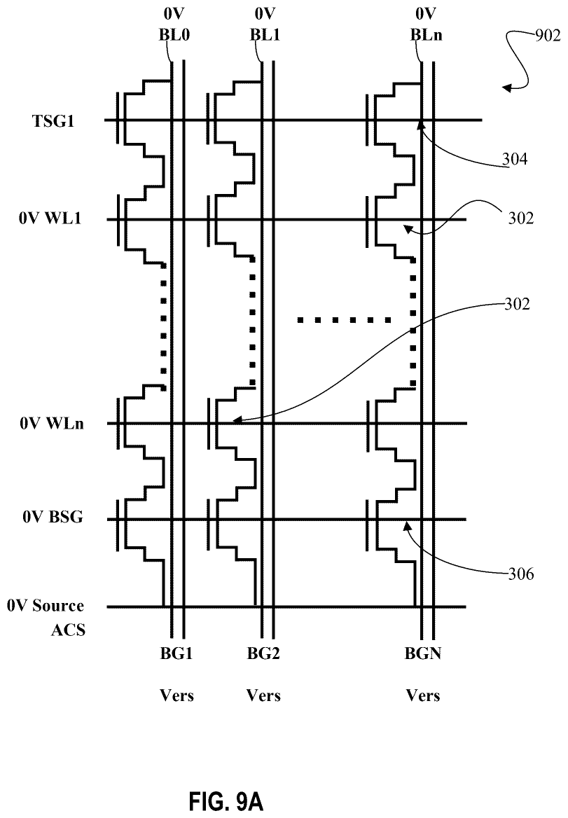

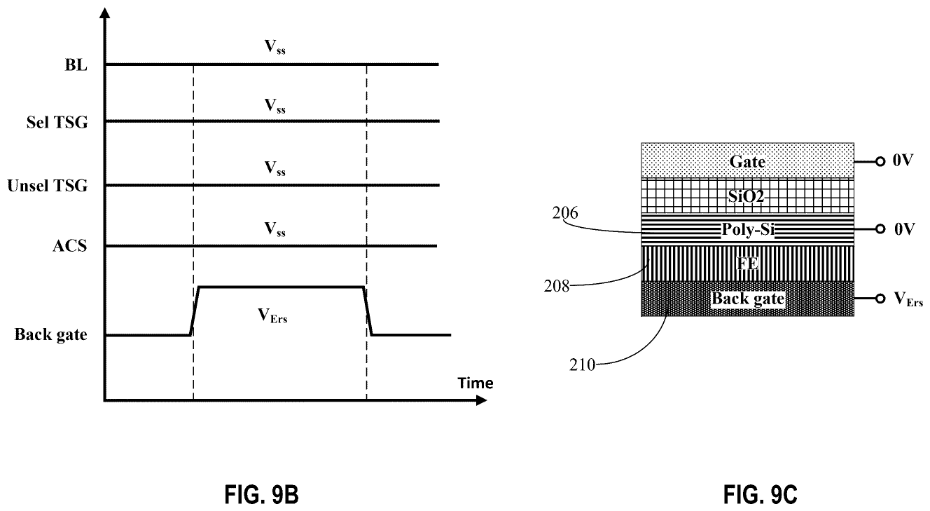

FIG. 9A illustrates a schematic circuit diagram of the example ferroelectric memory array 300 of FIG. 3A during an erase operation. FIG. 9B illustrates an example signal diagram for erasing the example ferroelectric memory array 300. FIG. 9C illustrates voltages applied to a ferroelectric memory cell during the erase operation. For ease of description, reference will be made to FIGS. 9A-9C when describing the erase operation for the example ferroelectric memory array 300.

As illustrated in FIGS. 9A and 9B, in some implementations, to erase ferroelectric memory cells 302, the back gate BG1, . . . , and/or BGn can be biased with an erase voltage Vers, the ACS can be applied with a source line voltage (e.g., Vss), and the bit lines (e.g., BL0, . . . and/or BLn) can be applied with a bit line voltage (e.g., Vss). In some implementations, the source line voltage is 0V. In some implementations, the bit line voltage is 0V. The erase voltage can be greater than at least one of the source line voltage or the bit line voltage. In some implementations, the erase voltage is positive voltage. In some implementations, the erase voltage is between 5V and 10V.

During the erase operations, at least one of the TSG transistor 304 or the BSG transistor 306 can be switched on. Therefore, the channel layers 206 can be biased at 0V through the bit lines and/or source lines. In some implementations, the TSG transistor 304 is switched on, while the BSG transistor 306 is switched off. In some implementations, the TSG transistor 304 is switched off (e.g., as illustrated in FIG. 9B), while the BSG transistor 306 is switched on. In some implementations, both the TSG transistor 304 and the BSG transistor 306 are switched on.

As illustrated in FIG. 9C, the channel layer 206 of the ferroelectric memory cell can be biased at 0V, while the back gate 210 can be applied with a positive erase voltage Vers. Therefore, a high erase electric field can be generated between the back gate 210 and the channel layer 206. This high erase electric field can erase the data by altering the polarization state in the ferroelectric layer 208.

During the erase operations, the word lines WL1, WL2 . . . , and/or WLn can be applied with a first voltage (e.g., Vss). Vss can reduce the power consumption during the erase operation.

In some implementations, as illustrated in FIG. 9A, multiple memory cells 302 in a same memory block 902 are erased at the same time. To erase memory cells 302 in the selected memory block 902, the back gate BG1, . . . , BGn can all be biased with the erase voltage Vers, the ACS can be applied with the source line voltage (e.g., Vss), and the bit lines (e.g., BL0, . . . BLn) can all be applied with the bit line voltage (e.g., Vss). In some implementations, the back gate BG1, . . . , BGn in the same memory block 902 are coupled to each other. In some implementations, an erase operation can be performed at a half-block level, a quarter-block level, or a level having any suitable number of memory blocks or fractions of a memory block.

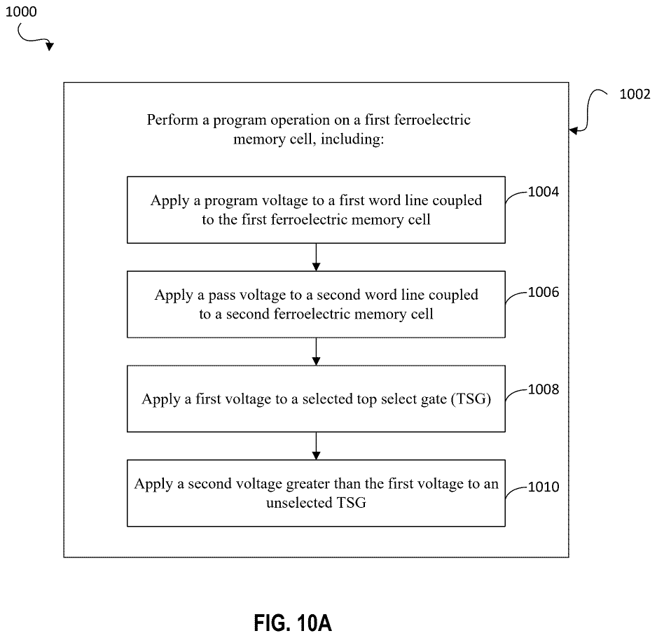

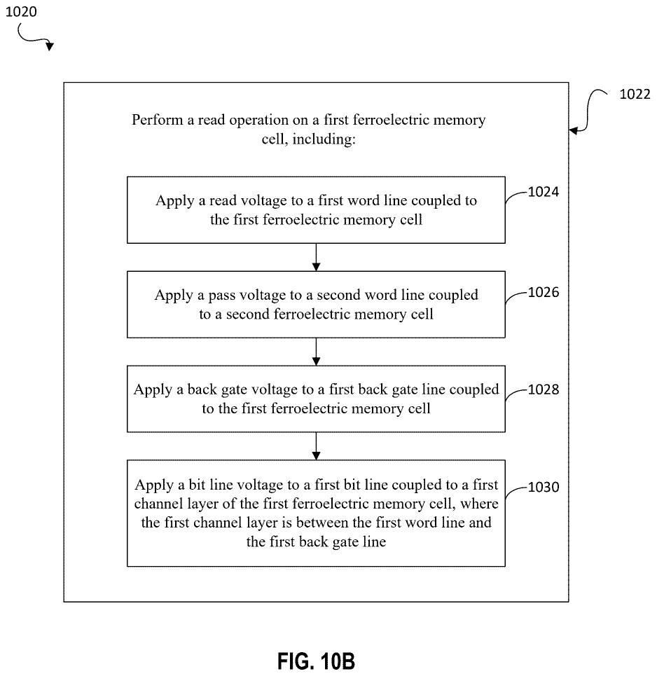

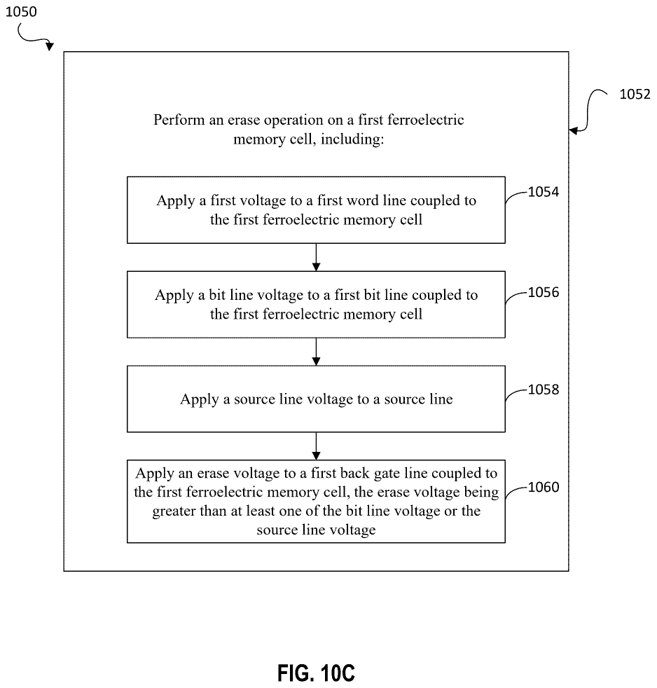

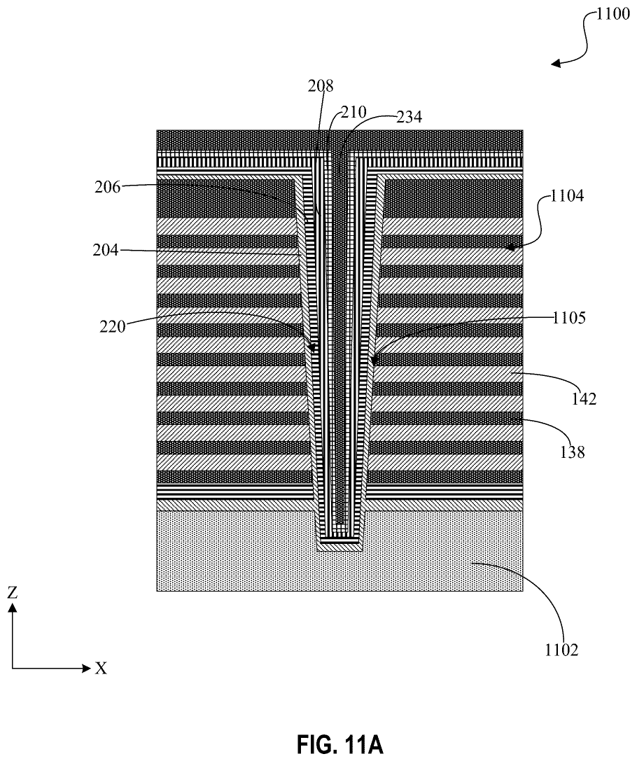

FIG. 10A is a flowchart of a process of an example method 1000 of programming a ferroelectric memory device. The ferroelectric memory device can be the first semiconductor structure 102 of FIGS. 1A and 1B, the first semiconductor structure 120 of FIG. 1C, the ferroelectric memory device 250 of FIG. 2D, the ferroelectric memory device 260 of FIG. 2E, or the ferroelectric memory array 300 of FIGS. 3, 6 and 9A.

At step 1002, a program operation is performed on a first ferroelectric memory cell. The first ferroelectric memory cell can be, e.g., the ferroelectric memory cell 150 of FIG. 1C, the ferroelectric memory cell 200 of FIG. 2B, the ferroelectric memory cell 240 of FIG. 2C, or the selected ferroelectric memory cell 302-1 of FIG. 3A. The program operation can include the following steps:

At step 1004, a program voltage is applied to a first word line coupled to the first ferroelectric memory cell. The program voltage can be, e.g., Vpgm of FIGS. 3-4E. The first word line can be, e.g., the conductive layer 136 of FIGS. 1C and 2B-2D, or WL1 of FIG. 3A;

At step 1006, a pass voltage is applied to a second word line coupled to a second ferroelectric memory cell. The pass voltage can be, e.g., Vpass of FIGS. 3-4E. The second ferroelectric memory cell can be, e.g., the ferroelectric memory cell 150 of FIG. 1C, the ferroelectric memory cell 200 of FIG. 2B, the ferroelectric memory cell 240 of FIG. 2C, or the unselected ferroelectric memory cell 302-n2 of FIG. 3A. The second word line can be, e.g., the conductive layer 136 of FIGS. 1C and 2B-2D, or any one of WL2, . . . , WLn of FIG. 3A;

At step 1008, a first voltage is applied to a selected top select gate (TSG). The first voltage can be, e.g., Vss. The selected TSG can be, e.g., the TSG1 of FIGS. 3A and 3B; and

At step 1010, a second voltage greater than the first voltage is applied to an unselected TSG. The second voltage can be, e.g., Vcon of FIG. 3A, or V_{TSG} of FIG. 4A. The unselected TSG can be, e.g., TSG2 of FIG. 3B.

In some implementations, the method includes applying a back gate voltage to a first back gate line coupled to the first ferroelectric memory cell (e.g., 302-1 of FIG. 3A) and a second back gate line coupled to the second ferroelectric memory cell; and applying a source line voltage to a source line coupled to the first ferroelectric memory cell and the second ferroelectric memory cell. The back gate voltage can be, e.g., Vss. The first back gate line can be, e.g., the back gate 210 of FIGS. 1C, 2B-2D, or back gate BG2 of FIG. 3A. The second back gate line can be, e.g., the back gate 210 of FIGS. 1C, 2B-2D, or any one of back gate BG1, BG3, . . . , BGn of FIG. 3A. In some examples, the second ferroelectric memory cell is the ferroelectric memory cell 302-n2 of FIG. 3A, and the second back gate line can be BGn of FIG. 3A. In some examples, the second ferroelectric memory cell is the ferroelectric memory cell 302-n of FIG. 3A, and the second back gate line can be the same as the first back gate line, e.g., BG2. The source line voltage can be, e.g., Vss. The source line can be, e.g., ACS of FIG. 3A.

In some implementations, the method includes applying a first bit line voltage to a first bit line coupled to the first ferroelectric memory cell; and applying a second bit line voltage to a second bit line coupled to a third ferroelectric memory cell, where the second bit line voltage is smaller than the first bit line voltage. The first bit line voltage can be, e.g., Vss. The second bit line voltage can be, e.g., Vinhibit of FIGS. 3 and 4A. The first bit line can be, e.g., bit line 112 of FIGS. 1C and 1D, or BL1 of FIGS. 3 and 4A. The second bit line can be, e.g., bit line 112 of FIGS. 1C and 1D, or any one of BL0, BL2, . . . , BLn of FIG. 3A, or BL0 of FIG. 4A.

In some implementations, the method includes applying the first bit line voltage to a third bit line. The third bit line can be, e.g., bit line 112 of FIGS. 1C and 1D, or any one of BL0, BL2, . . . , BLn of FIG. 3A, or BL0 of FIG. 4A, that is different from the second bit line.

In some implementations, the first ferroelectric memory cell includes: a front gate including a part of the first word line; a dielectric layer in contact with the front gate; a first channel layer in contact with the dielectric layer; a ferroelectric layer in contact with the first channel layer; and a first back gate in contact with the ferroelectric layer and including a part of the first back gate line, where the first channel layer is between the front gate and the first back gate, and the ferroelectric layer is between the first channel layer and the first back gate. The front gate can be, e.g., the conductive layer 136 of FIGS. 1C and 2B-2D, or word lines WL1, . . . WLn of FIGS. 3A, 6 and 9. The dielectric layer can be, e.g., the dielectric layer 204 of FIGS. 1C and 2B-2D. The first channel layer can be, e.g., the channel layer 206 of FIGS. 1C and 2B-2D. The ferroelectric layer can be, e.g., the ferroelectric layer 208 of FIGS. 1C and 2A-2D. The first back gate can be, e.g., the back gate 210 of FIGS. 1C and 2B-2D.

In some implementations, the first voltage is zero.

In some implementations, the second voltage is between 0 and 10V.

In some implementations, the program voltage is between 5V and 10V, the pass voltage is between 4 and 8V, and the program voltage is greater than the pass voltage.

FIG. 10B is a flowchart of a process of an example method 1020 of reading a ferroelectric memory device. The ferroelectric memory device can be the first semiconductor structure 102 of FIGS. 1A and 1B, the first semiconductor structure 120 of FIG. 1C, the ferroelectric memory device 250 of FIG. 2D, the ferroelectric memory device 260 of FIG. 2E, or the ferroelectric memory array 300 of FIGS. 3, 6 and 9A.

At step 1022, a read operation is performed on a first ferroelectric memory cell. The first ferroelectric memory cell can be, e.g., the ferroelectric memory cell 150 of FIG. 1C, the ferroelectric memory cell 200 of FIG. 2B, the ferroelectric memory cell 240 of FIG. 2C, or the selected ferroelectric memory cell 302-1 of FIG. 6. The read operation can include the following steps:

At step 1024, a read voltage is applied to a first word line coupled to the first ferroelectric memory cell. The read voltage can be, e.g., Vread of FIGS. 6-7D. The first word line can be, e.g., the conductive layer 136 of FIGS. 1C and 2B-2D, or WL1 of FIG. 6;

At step 1026, a pass voltage is applied to a second word line coupled to a second ferroelectric memory cell. The pass voltage can be, e.g., Vpass of FIGS. 6-7D. The second ferroelectric memory cell can be, e.g., the ferroelectric memory cell 150 of FIG. 1C, the ferroelectric memory cell 200 of FIG. 2B, the ferroelectric memory cell 240 of FIG. 2C, or the unselected ferroelectric memory cell 302-n2 of FIG. 6. The second word line can be, e.g., the conductive layer 136 of FIGS. 1C and 2B-2D, or any one of WL2, . . . , WLn of FIG. 6;

At step 1028, a back gate voltage is applied to a first back gate line coupled to the first ferroelectric memory cell. The back gate voltage can be, e.g., Vss. The first back gate line can be, e.g., the back gate 210 of FIGS. 1C, 2B-2D, or back gate BG2 of FIG. 6; and

At step 1030, a bit line voltage is applied to a first bit line coupled to a first channel layer of the first ferroelectric memory cell, where the first channel layer is between the first word line and the first back gate line. The bit line voltage can be, e.g., V_{BL} of FIGS. 6 and 7A. The first bit line can be, e.g., bit line 112 of FIGS. 1C and 1D, BL1 of FIG. 6, or BL of FIG. 7A. The first channel layer can be, e.g., the channel layer 206 of FIGS. 1C and 2B-2D.

In some implementations, the method includes applying a first voltage to a selected top select gate (TSG); and applying a second voltage smaller than the first voltage to an unselected TSG. The first voltage can be, e.g., Vcon of FIG. 6, or V_{TSG} of FIG. 7A. The second voltage can be, e.g., Vss.

In some implementations, the first ferroelectric memory cell includes: a front gate including a part of the first word line; a dielectric layer in contact with the front gate; the first channel layer in contact with the dielectric layer; a ferroelectric layer in contact with the first channel layer; and a first back gate in contact with the ferroelectric layer and including a part of the first back gate line, where the ferroelectric layer is between the first channel layer and the first back gate. The front gate can be, e.g., the conductive layer 136 of FIGS. 1C and 2B-2D, or word lines WL1, . . . WLn of FIGS. 3A, 6 and 9. The dielectric layer can be, e.g., the dielectric layer 204 of FIGS. 1C and 2B-2D. The first channel layer can be, e.g., the channel layer 206 of FIGS. 1C and 2B-2D. The ferroelectric layer can be, e.g., the ferroelectric layer 208 of FIGS. 1C and 2A-2D. The first back gate can be, e.g., the back gate 210 of FIGS. 1C and 2B-2D.

In some implementations, the back gate voltage is zero.

In some implementations, the bit line voltage is between 0 and 5V.

In some implementations, the read voltage is between −5V and 5V.

FIG. 10C is a flowchart of a process of an example method 1050 of erasing a ferroelectric memory device. The ferroelectric memory device can be the first semiconductor structure 102 of FIGS. 1A and 1B, the first semiconductor structure 120 of FIG. 1C, the ferroelectric memory device 250 of FIG. 2D, the ferroelectric memory device 260 of FIG. 2E, or the ferroelectric memory array 300 of FIGS. 3, 6 and 9A.

At step 1052, an erase operation is performed on a first ferroelectric memory cell. The first ferroelectric memory cell can be, e.g., the ferroelectric memory cell 150 of FIG. 1C, the ferroelectric memory cell 200 of FIG. 2B, the ferroelectric memory cell 240 of FIG. 2C, or the selected ferroelectric memory cell 302-1 of FIG. 9A. The erase operation can include the following steps:

At step 1054, a first voltage is applied to a first word line coupled to the first ferroelectric memory cell. The first voltage can be, e.g., Vss. The first word line can be, e.g., the conductive layer 136 of FIGS. 1C and 2B-2D, or WL1 of FIG. 9A;

At step 1056, a bit line voltage is applied to a first bit line coupled to the first ferroelectric memory cell. The bit line voltage can be, e.g., Vss. The first bit line can be, e.g., bit line 112 of FIGS. 1C and 1D, or BL1 of FIG. 9A, or BL of FIG. 9B;

At step 1058, a source line voltage is applied to a source line. The source line voltage can be, e.g., Vss. The source line can be, e.g., ACS of FIGS. 9A and 9B; and

At step 1060, an erase voltage is applied to a first back gate line coupled to the first ferroelectric memory cell, the erase voltage being greater than the bit line voltage. The erase voltage can be, e.g., Vers of FIGS. 9A and 9B. The first back gate line can be, e.g., the back gate 210 of FIGS. 1C, 2B-2D, back gate BG2 of FIG. 9A, or back gate of FIG. 9B.

In some implementations, at least one of the bit line voltage or the source line voltage is zero.

In some implementations, the method includes performing the erase operation on the first ferroelectric memory cell and a second ferroelectric memory cell in a same erase phase by: applying the first voltage to a second word line coupled to the second ferroelectric memory cell; applying a second bit line voltage to a second bit line coupled to the second ferroelectric memory cell; applying the source line voltage the source line; and applying the erase voltage to a second back gate line coupled to the second ferroelectric memory cell, where the first back gate line is coupled to the second back gate line. The second word line can be, e.g., the conductive layer 136 of FIGS. 1C and 2B-2D, or any one of WL2, . . . , WLn of FIG. 9A. The second bit line voltage can be, e.g., Vss. The second bit line can be, e.g., bit line 112 of FIGS. 1C and 1D, or any one of BL0, BL2, . . . , BLn of FIG. 9A. The second back gate line can be, e.g., the back gate 210 of FIGS. 1C, 2B-2D, or any one of back gate BG1, BG3, . . . , BGn of FIG. 9A.

In some implementations, the erase voltage is between 5V and 10V.

In some implementations, the first voltage is zero.

In some implementations, the first ferroelectric memory cell includes: a front gate including a part of the first word line; a dielectric layer in contact with the front gate; a first channel layer in contact with the dielectric layer; a ferroelectric layer in contact with the first channel layer; and a first back gate in contact with the ferroelectric layer and including a part of the first back gate line, where the first channel layer is between the front gate and the first back gate, and the ferroelectric layer is between the first channel layer and the first back gate. The front gate can be, e.g., the conductive layer 136 of FIGS. 1C and 2B-2D, or word lines WL1, . . . WLn of FIGS. 3A, 6 and 9. The dielectric layer can be, e.g., the dielectric layer 204 of FIGS. 1C and 2B-2D. The first channel layer can be, e.g., the channel layer 206 of FIGS. 1C and 2B-2D. The ferroelectric layer can be, e.g., the ferroelectric layer 208 of FIGS. 1C and 2A-2D. The first back gate can be, e.g., the back gate 210 of FIGS. 1C and 2B-2D.

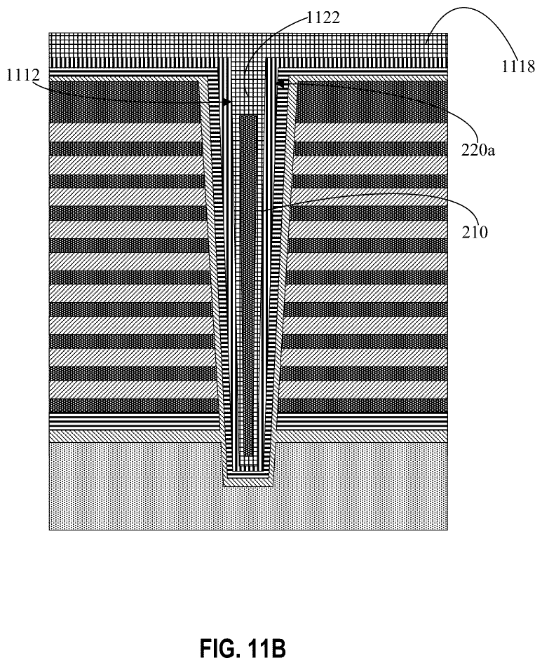

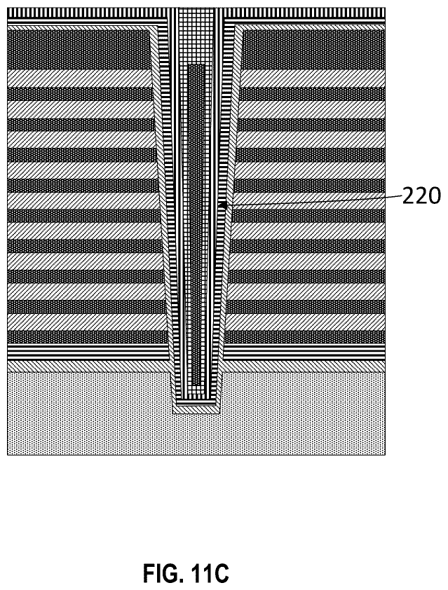

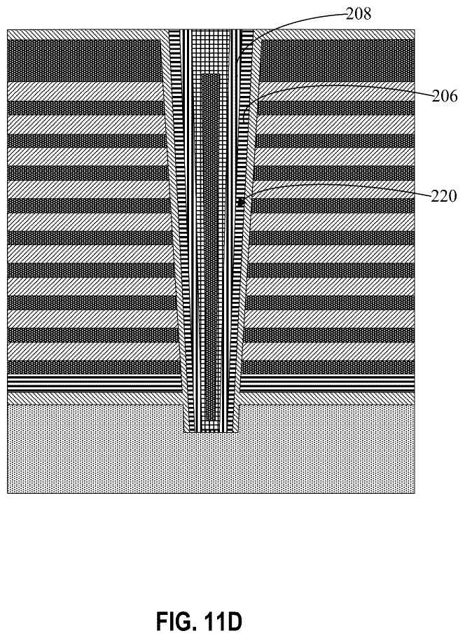

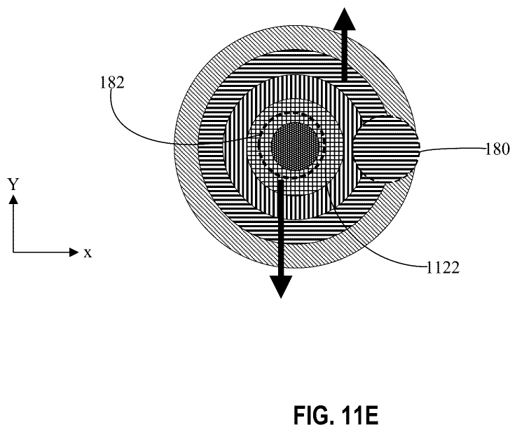

FIGS. 11A-11D illustrate cross-sectional views of an example ferroelectric memory device 1100 at various stages of a fabrication process. FIG. 11E illustrates a top view of the example ferroelectric memory device 1100 at a stage of the fabrication process. The ferroelectric memory device 1100 can be the first semiconductor structure 102 of FIGS. 1A and 1B, the first semiconductor structure 120 of FIG. 1C, the ferroelectric memory cell 200 of FIG. 2B, the ferroelectric memory cell 240 of FIG. 2C, the ferroelectric memory device 250 of FIG. 2D, the ferroelectric memory device 260 of FIG. 2E, or the ferroelectric memory array 300 of FIGS. 3, 6 and 9A.

As illustrated in FIG. 11A, an initial stack structure 1104 can be formed on a substrate 1102. The initial stack structure 1104 can include separation layers 142 and isolating layers 138 alternating with each other along the first direction (e.g., Z direction). The isolating layers 138 can be the isolating layers 138 of FIG. 1C. In some implementations, the isolating layers 138 and/or the separation layers 142 include dielectric materials including, but not limited to, silicon oxide, silicon nitride, silicon oxynitride, or any combination thereof. In some implementations, the separation layers 142 can include a dielectric material different from the dielectric material of the isolating layers 138. For example, the isolating layers 138 can include silicon oxide, while the separation layers 142 can include silicon nitride. The separation layers 142 can be replaced with the conductive layers 136 at later stages of the process.

A hole 1105 can be formed extending through the initial stack structure 1104 along Z direction. A string structure 220 can formed by depositing a dielectric layer 204, a channel layer 206, a ferroelectric layer 208, a second conductive layer 210 and an inner layer 234 into the hole 1105. As illustrated in FIG. 11A, the channel layer 206 is between at least one of the first conductive layers 136 and the second conductive layer 210 along a second direction (e.g., x direction), and the ferroelectric layer 208 is between the channel layer 206 and the second conductive layer 210 along the second direction (e.g., x direction).

As noted above, in some implementations, the second conductive layer 210 includes at least one of a metallic material or polysilicon. For example, the second conductive layer 210 can include, but not limited to W, Co, Cu, Al, TiN, TaN, polysilicon, silicide, or any combination thereof. In some implementations, the second conductive layer 210 includes multiple conductive layers, such as a W layer over a TiN layer. The second conductive layer 210 can also be referred to as back gate 210 in the present disclosure.

In some implementations, the ferroelectric layer 208 includes at least one of Lead Zirconate Titanate (PZT), Strontium Bismuth Tantalate (SBT), Zirconium-doped Hafnium Dioxide (Zr:HfO₂), Aluminum-doped Hafnium Dioxide (Al:HfO₂), Silicon-doped Hafnium Dioxide (Si:HfO₂), Diindium Triselenide (In₂Se₃), indium Selenide (InSe), or Copper Indium Phosphorus Sulfide (CuInP₂S₆). Without limiting to any particular theory, the ferroelectric layer 208 can be made of a ferroelectric material that has spontaneous electric polarization that can be reversed by an applied electric field. In some implementations, the first dielectric layer 204 includes dielectric materials including, but not limited to, silicon oxide, silicon nitride, silicon oxynitride, or any combination thereof.

Forming the string structure 220 can include one or more thin film deposition techniques, including, but not limited to, chemical vapor deposition (CVD), physical vapor deposition (PVD), plasma enhanced chemical vapor deposition (PECVD) atomic layer deposition (ALD), sputtering, or any combination thereof. In some implementations, the ferroelectric layer is deposited by ALD. In some implementations, the inner layer 234 is deposited by ALD.

As illustrated in FIG. 11B, a first plug 1122 can be formed in a first end 220a of the string structure 220. The first plug 1122 can be the first plug 222 of FIG. 2E. Forming the first plug 222 can include recessing a portion of the inner layer 234 in the first end 220a of the string structure 220 to form a first opening 1112; and depositing a first conductive material 1118 in the first opening 1112. The first conductive material 1118 can be in contact with the second conductive layer 210. In some implementations, the first conductive material 1118 can include the same material as the second conductive layer 210. In some implementations, the first conductive material 1118 includes, but not limited to W, Co, Cu, Al, TiN, TaN, polysilicon, silicide, or any combination thereof. The first plug 222 can provide a greater surface area, enabling a wider processing window for landing the second contact structure (e.g., the second contact structure 182 of FIG. 1C) on the first plug 222 to couple out the second conductive layer 210 to control circuits. The etching process can involve dry etching techniques, including without limitation to, reactive icon etching (RIE), inductively coupled plasma (ICP) etching, deep reactive ion etching (DRIE), ion beam etching (IBE), plasma etching, or chemical vapor etching (CVE). The first conductive material 1118 can be deposited by one or more thin film deposition processes including, but not limited to, chemical vapor deposition (CVD), physical vapor deposition (PVD), atomic layer deposition (ALD), Metal-Organic Chemical Vapor Deposition (MOCVD), sputtering, electroplating, electroless plating, electron-beam evaporation, or any combination thereof.

As illustrated in FIG. 11C, one or more polishing processes can be performed to remove the first conductive material 1118 outside the string structure 220. The one or more polishing processes can involve chemical mechanical polishing (CMP).

As illustrated in FIG. 11D, one or more polishing processes can be performed to remove the channel layer 206 and the ferroelectric layer 208 outside the string structure 220. The one or more polishing processes can involve chemical mechanical polishing (CMP).

As illustrated FIG. 11E, a first contact structure 180 and a second contact structure 182 can be formed. The first contact structure 180 can be the first contact structure 180 of FIG. 1C, and the second contact structure 182 can be the second contact structure 182 of FIG. 1C. The first contact structure 180 can be overlapped with the channel layer 206 and coupled to the channel layer 206, while the second contact structure 182 can be overlapped with the second conductive layer 210 (e.g., back gate) and coupled to the second conductive layer 210. The first contact structure 180 can couple out the channel layer 206 to control circuits, while the second contact structure 182 can couple out the second conductive layer 210 to the control circuits.

In some implementations, the first contact structure 180 and the second contact structure 182 can be formed at one or more same process steps. For example, forming the first contact structure 180 and the second contact structure 182 can include: depositing a interdielectric layer (ILD) above the initial stack structure 1104; forming a first contact hole and a second contact hole extending through the ILD in a same lithography process, where the first contact hole can expose the underlying channel layer 206, and the second contact hole can expose the underlying back gate 210; and depositing a conductive material into the first and second contact hole to form the first and second contact structure 180, 182, respectively. In some implementations, the first and second contact structure 180, 182 can include material, but not limited to, TiN, TaN, Al, W, Cu, doped-polysilicon, silicides, or any combination thereof.

With continued reference to FIG. 11E, as noted above, the first plug 222 that is coupled to the second conductive layer 210 can provide a greater surface area, enabling a wider processing window for landing the second contact structure 182 on the first plug 222 to couple out the second conductive layer 210 to control circuits.

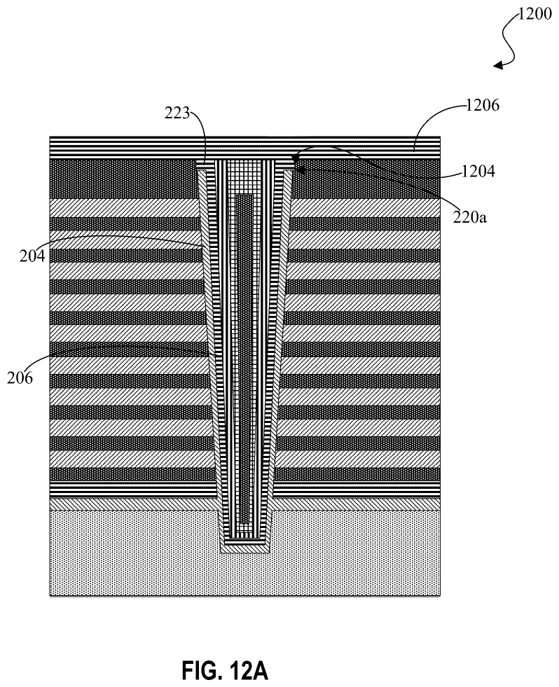

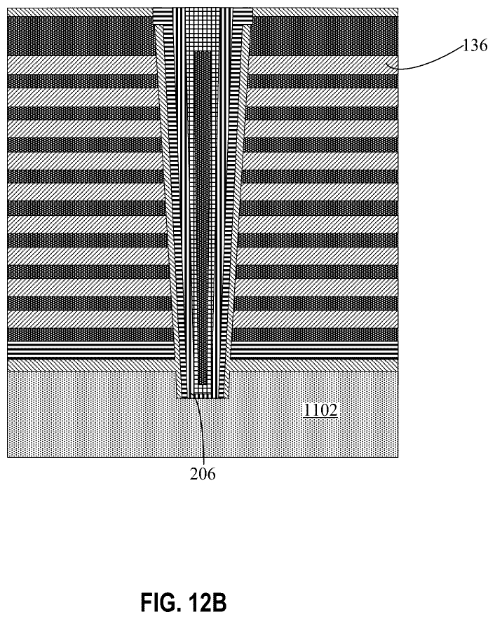

FIGS. 12A-12B illustrate cross-sectional views of another example ferroelectric memory device 1200 at various stages of a fabrication process. The ferroelectric memory device 1200 can be the first semiconductor structure 102 of FIGS. 1A and 1B, the first semiconductor structure 120 of FIG. 1C, the ferroelectric memory cell 200 of FIG. 2B, the ferroelectric memory cell 240 of FIG. 2C, the ferroelectric memory device 250 of FIG. 2D, the ferroelectric memory device 260 of FIG. 2E, or the ferroelectric memory array 300 of FIGS. 3, 6 and 9A.

After the process step illustrated in FIG. 11C, as illustrated in FIG. 12A, a second plug 223 in the first end 220a of the string structure 220 can be formed. Forming the second plug 223 can include: recessing a portion of the dielectric layer 204 and the channel layer 206 in the first end 220a of the string structure 220 to form a second opening 1204; and depositing a second conductive material 1206 in the second opening 1204, where the second conductive material 1206 is in contact with the channel layer 206. The second conductive material 1206 can include the same material or different material compared to the channel layer 206. In some implementations, the second conductive material 1206 includes, but not limited to W, Co, Cu, Al, TiN, TaN, polysilicon, silicide, or any combination thereof.

As illustrated in FIG. 12B, a part of the second conductive material 1206 that is outside the string structure 220 can be removed by at least one polishing process. The at least one polishing process can involve chemical mechanical polishing (CMP). The second plug 223 can provide a greater surface area, enabling a wider processing window for landing the first contact structure (e.g., the first contact structure 180 of FIG. 1C) on the second plug 223 to couple out the channel layer 206 to control circuits. Wider processing window can improve manufacturing yield, and enhance device reliability.

In some implementations, the separation layers 142 of the initial stack structure 1104 can be replaced with first conductive layers 136 to form the stack structure (e.g., the stack structure 130 of FIGS. 1C, 2D and 2E). The replacement process can involve plurality of processes including, but not limited to, photolithography, dry/wet etch, thin film deposition, thermal growth, implantation, chemical mechanical polishing (CMP), and/or any other suitable processes. In some implementations, the channel layer 206 of the string structure can be exposed to the substrate 1102. At least a part of the substrate 1102 can be doped to form a source line (not shown), and the channel layer 206 can be coupled to the source line or the doped region of the substrate 1102.

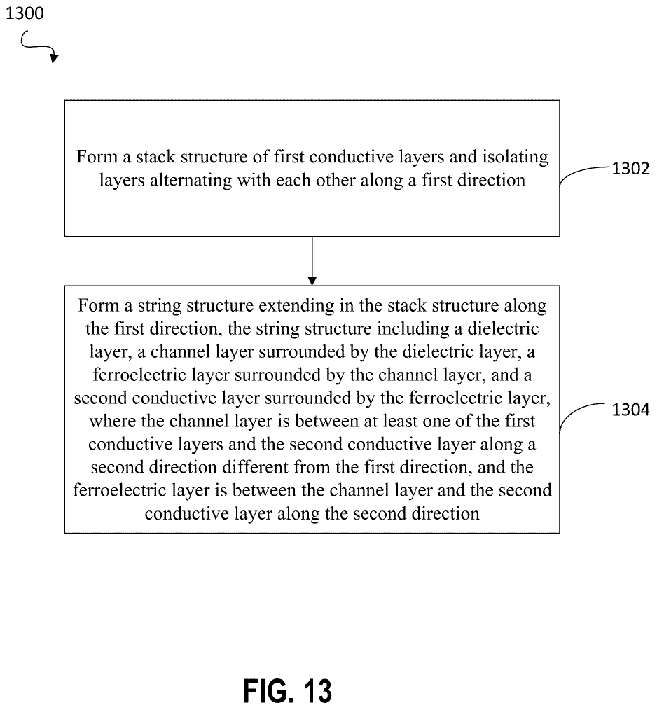

FIG. 13 is a flow chart of a process of an example method 1300 to form a ferroelectric memory device. The ferroelectric memory device can be the first semiconductor structure 102 of FIGS. 1A and 1B, the first semiconductor structure 120 of FIG. 1C, the ferroelectric memory device 250 of FIG. 2D, the ferroelectric memory device 260 of FIG. 2E, the ferroelectric memory array 300 of FIGS. 3, 6 and 9A, the ferroelectric memory device 1100 or a part of the ferroelectric memory device 1100 of FIGS. 11A-11E, or the ferroelectric memory device 1200 or a part of the ferroelectric memory device 1200 of FIGS. 12A-12B.

At step 1302, a stack structure is formed. The stack structure includes first conductive layers and isolating layers alternating with each other along a first direction. The stack structure can be, e.g., the stack structure 130 of FIGS. 1C, 2D and 2E. The first conductive layers can be, e.g., the conductive layer 136 of FIGS. 1C and 2B-2D, or word lines WL1, . . . WLn of FIGS. 3A, 6 and 9. The isolating layers can be, e.g., the isolating layers 138 of FIGS. 1C, 2D-2E, and 11A-12B.

At step 1304, a string structure is formed extending in the stack structure along the first direction, the string structure including a dielectric layer, a channel layer surrounded by the dielectric layer, a ferroelectric layer surrounded by the channel layer, and a second conductive layer surrounded by the ferroelectric layer, where the channel layer is between at least one of the first conductive layers and the second conductive layer along a second direction different from the first direction, and the ferroelectric layer is between the channel layer and the second conductive layer along the second direction. The string structure can be, e.g., the string structure 220 of FIGS. 1C, 2D-2E, and 11A-12B. The dielectric layer can be, e.g., the dielectric layer 204 of FIGS. 1C, 2B-2E, and 11A-12B. The first channel layer can be, e.g., the channel layer 206 of FIGS. 1C, 2B-2E, and 11A-12B. The ferroelectric layer can be, e.g., the ferroelectric layer 208 of FIGS. 1C, 2A-2E, and 11A-12B. The second conductive layer can be, e.g., the back gate 210 of FIGS. 1C, 2B-2E, and 11A-12B.

In some implementations, forming the stack structure includes forming an initial stack structure of separation layers and the isolating layers alternating with each other along the first direction, The string structure includes an inner layer. Forming the string structure extending in the stack structure includes: forming a hole extending in the initial stack structure; and depositing the dielectric layer, the channel layer, the ferroelectric layer, the second conductive layer and the inner layer into the hole. The initial stack structure can be, e.g., the initial stack structure 1104 of FIGS. 11A-12B. The separation layers can be, e.g., the separation layers 142 of FIGS. 11A-12B. The inner layer can be, e.g., the inner layer 234 of FIGS. 2E and 11A-12B. The hole can be, e.g., the hole 1105 of FIG. 11A.

In some implementations, the method includes forming a first plug structure in a first end of the string structure, including: recessing a portion of the inner layer in the first end of the string structure to form a first opening; and depositing a first conductive material in the first opening, where the first conductive material is in contact with the second conductive layer. The first plug structure can be, e.g., the first plug 222 of FIG. 2E, or the first plug 1122 of FIGS. 11B-12B. The first end of the string structure can be, e.g., the first end 220a of the string structure 220 of FIGS. 2E and 11B-12B. The first opening can be, e.g., the first opening 1112 of FIG. 11B. The first conductive material can be, e.g., the first conductive material 1118 of FIG. 11B.

In some implementations, the method includes removing the first conductive material outside the string structure by at least one polishing process.

In some implementations, the method includes forming a second plug structure in the first end of the string structure, including: recessing a portion of the dielectric layer and the channel layer in the first end of the string structure to form a second opening; and depositing a second conductive material in the second opening, where the second conductive material is in contact with the channel layer. The second plug structure can be, e.g., the second plug 223 of FIGS. 2E and 12A-12B. The second opening can be, e.g., the second opening 1204 of FIG. 12A. The second conductive material can be, e.g., the second conductive material 1206 of FIG. 12A.

In some implementations, the method includes: removing a part of the second conductive material and a part of the first conductive material that is outside the string structure by at least one polishing process.

In some implementations, forming the stack structure includes: replacing the separation layers of the initial stack structure with the first conductive layers.

In some implementations, the method includes forming a first contact structure coupled to the channel layer and a second contact structure coupled to the second conductive layer at one or more same process steps. The first contact structure can be, e.g., the first contact structure 180 of FIGS. 1C and 11E, or bit lines 112 of FIGS. 1C and 1D. the second contact structure can be, e.g., the second contact structure 182 of FIGS. 1C and 11E, or BG control lines 113 of FIGS. 1C and 1D.

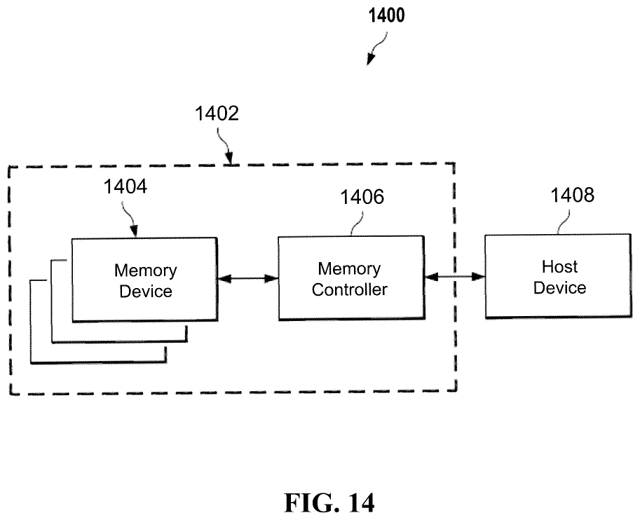

FIG. 14 illustrates a block diagram of a system 1400 having one or more semiconductor devices (e.g., memory devices), according to one or more implementations of the present disclosure. The system 1400 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 14, the system 1400 can include a host device 1408 and a memory system 1402 having one or more 3D memory devices 1404 and a memory controller 1406. Host device 1408 can include a processor of an electronic device, such as a central processing unit (CPU), or a system-on-chip (SoC), such as an application processor (AP). Host device 1408 can be configured to send or receive data to or from the one or more 3D memory devices 1404.

A 3D memory device 1404 can be any 3D memory device disclosed herein, such as the first semiconductor structure 102 of FIGS. 1A and 1B, the first semiconductor structure 120 of FIG. 1C, the ferroelectric memory device 250 of FIG. 2D, the ferroelectric memory device 260 of FIG. 2E, the ferroelectric memory array 300 of FIGS. 3, 6 and 9A, the ferroelectric memory device 1100 or a part of the ferroelectric memory device 1100 of FIGS. 11A-11E, or the ferroelectric memory device 1200 or a part of the ferroelectric memory device 1200 of FIGS. 12A-12B.

In some implementations, a 3D memory device 1404 includes a ferroelectric memory device, or a FE-NAND device. Memory controller 1406 (a.k.a., a controller circuit) is coupled to 3D memory device 1404 and host device 1408. Consistent with implementations of the present disclosure, 3D memory device 1404 can include a plurality of conductive interconnections through a cover layer that are in contact with conductive pads in a conductive pad layer, and memory controller 1406 can be coupled to 3D memory device 1404 through at least one of the plurality of conductive interconnections. Memory controller 1406 is configured to control 3D memory device 1404. For example, memory controller 1406 may be configured to operate a plurality of channel structures via word lines. Memory controller 1406 can manage data stored in 3D memory device 1404 and communicate with host device 1408.

In some implementations, memory controller 1406 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 1406 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 1406 can be configured to control operations of 3D memory device 1404, such as read, erase, and program (or write) operations. Memory controller 1406 can also be configured to manage various functions with respect to the data stored or to be stored in 3D memory device 1404 including, but not limited to bad-block management, garbage collection, logical-to-physical address conversion, wear leveling, etc. In some implementations, memory controller 1406 is further configured to process error correction codes (ECCs) with respect to the data read from or written to 3D memory device 1404. Any other suitable functions may be performed by memory controller 1406 as well, for example, formatting 3D memory device 1404.

Memory controller 1406 can communicate with an external device (e.g., host device 1408) according to a particular communication protocol. For example, memory controller 1406 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 1406 and one or more 3D memory devices 1404 can be integrated into various types of storage devices, for example, be included in the same package, such as a universal Flash storage (UFS) package or an eMMC package. That is, memory system 1402 can be implemented and packaged into different types of end electronic products. In one example as shown in FIG. 14, memory controller 1406 and a single 3D memory device 1404 may be integrated into a memory card 1402. Memory card 1402 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one implementation,” “an implementation,” “an example implementation,” “some implementations,” etc., indicate that the implementation described can include a particular feature, structure, or characteristic, but every implementation can not necessarily include the particular feature, structure, or characteristic. Moreover, such phrases do not necessarily refer to the same implementation. Further, when a particular feature, structure or characteristic is described in connection with an implementation, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (e.g., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+ conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layer 204s.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances.

The terms “approximately,” and “about,” as used herein represent an amount close to the stated amount that still performs a desired function or achieves a desired result. For example, the terms “approximately,” “about,” and “substantially” may refer to an amount that is within less than 5% of, within less than 1% of, within less than 0.1% of, and within less than 0.01% of a stated amount. e.g., .+−0.10%, .+−0.20%, or .+−0.30% of the value), but is not limited thereto.

As used in this disclosure, the term “substantially” or “substantial” refers to a majority of, or mostly, as in at least about 50%, 60%, 70%, 80%, 90%, 95%, 96%, 97%, 98%, 99%, 99.5%, 99.9%, 99.99%, or at least about 99.999% or more.

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

As used herein, the term “surrounded by” refers to at least partially surrounded by. For example, A is surrounded by B can refer to that A is at least partially surrounded by B.

As used herein, the term “and/or” as used herein refers to and encompasses any and all possible combinations of one or more of the associated listed terms. For example, the term “A and/or B” means that either option A, option B, or both options A and B are possible, where A and B may be singular or plural.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single implementation. Conversely, various features that are described in the context of a single implementation can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A method of operating a ferroelectric memory device, comprising:
performing a program operation on a first ferroelectric memory cell, comprising:
applying a program voltage to a first word line coupled to the first ferroelectric memory cell;
applying a pass voltage to a second word line coupled to a second ferroelectric memory cell;
applying a first voltage to a selected top select gate (TSG); and
applying a second voltage greater than the first voltage to an unselected TSG.

2. The method of claim 1, comprising:
applying a back gate voltage to a first back gate line coupled to the first ferroelectric memory cell and a second back gate line coupled to the second ferroelectric memory cell; and
applying a source line voltage to a source line coupled to the first ferroelectric memory cell and the second ferroelectric memory cell.

3. The method of claim 1, comprising:
applying a first bit line voltage to a first bit line coupled to the first ferroelectric memory cell; and
applying a second bit line voltage to a second bit line coupled to a third ferroelectric memory cell, wherein the second bit line voltage is smaller than the first bit line voltage.

4. The method of claim 2, wherein the first ferroelectric memory cell comprises:
a front gate comprising a part of the first word line;
a dielectric layer in contact with the front gate;
a first channel layer in contact with the dielectric layer;
a ferroelectric layer in contact with the first channel layer; and
a first back gate in contact with the ferroelectric layer and comprising a part of the first back gate line,
wherein the first channel layer is between the front gate and the first back gate, and the ferroelectric layer is between the first channel layer and the first back gate.

5. The method of claim 1, wherein the first voltage is zero.

6. The method of claim 1, wherein the second voltage is between 0.5V and 10V.

7. The method of claim 1, wherein the program voltage is between 5V and 10V, the pass voltage is between 4 and 8V, and the program voltage is greater than the pass voltage.

8. A method of operating a ferroelectric memory device, comprising:
performing a read operation on a first ferroelectric memory cell, comprising:
applying a read voltage to a first word line coupled to the first ferroelectric memory cell;
applying a pass voltage to a second word line coupled to a second ferroelectric memory cell;
applying a back gate voltage to a first back gate line coupled to the first ferroelectric memory cell; and
applying a bit line voltage to a first bit line coupled to a first channel layer of the first ferroelectric memory cell,
wherein the first channel layer is between the first word line and the first back gate line.

9. The method of claim 8, comprising:
applying a first voltage to a selected top select gate (TSG); and
applying a second voltage smaller than the first voltage to an unselected TSG.

10. The method of claim 8, wherein the first ferroelectric memory cell comprises:
a front gate comprising a part of the first word line;
a dielectric layer in contact with the front gate;
the first channel layer in contact with the dielectric layer;
a ferroelectric layer in contact with the first channel layer; and
a first back gate in contact with the ferroelectric layer and comprising a part of the first back gate line,
wherein the ferroelectric layer is between the first channel layer and the first back gate.

11. The method of claim 8, wherein the back gate voltage is zero.

12. The method of claim 8, wherein the bit line voltage is between 0 and 5V.

13. The method of claim 8, wherein the read voltage is between −5V and 5V.

14. A method of operating a memory device, comprising:
performing an erase operation on a first ferroelectric memory cell, comprising:
applying a first voltage to a first word line coupled to the first ferroelectric memory cell;
applying a bit line voltage to a first bit line coupled to the first ferroelectric memory cell;
applying a source line voltage to a source line; and
applying an erase voltage to a first back gate line coupled to the first ferroelectric memory cell, the erase voltage being greater than at least one of the bit line voltage or the source line voltage.

15. The method of claim 14, wherein at least one of the bit line voltage or the source line voltage is zero.

16. The method of claim 14, comprising:
applying a second voltage to a top select gate (TSG).

17. The method of claim 14, comprising:
performing the erase operation on the first ferroelectric memory cell and a second ferroelectric memory cell in a same erase phase by:
applying the first voltage to a second word line coupled to the second ferroelectric memory cell;
applying a second bit line voltage to a second bit line coupled to the second ferroelectric memory cell;
applying the source line voltage the source line; and
applying the erase voltage to a second back gate line coupled to the second ferroelectric memory cell,
wherein the first back gate line is coupled to the second back gate line.

18. The method of claim 14, wherein the erase voltage is between 5V and 10V.

19. The method of claim 14, wherein the first voltage is zero.

20. The method of claim 14, wherein the first ferroelectric memory cell comprises:
a front gate comprising a part of the first word line;
a dielectric layer in contact with the front gate;
a first channel layer in contact with the dielectric layer;
a ferroelectric layer in contact with the first channel layer; and
a first back gate in contact with the ferroelectric layer and comprising a part of the first back gate line,
wherein the first channel layer is between the front gate and the first back gate, and the ferroelectric layer is between the first channel layer and the first back gate.
